(19) United States
(12) Patent Application Publication
(10) Pub. No.: US 2007/0246818 A1
(43) Pub. Date: Oct. 25, 2007

(54) Semiconductor module featuring solder balls having lower melting point than that of solder electrode terminals of electronic device containing additional metal powder component

(75) Inventors: Daisuke Ejima, Kanagawa (JP); Tsuyoshi Kida, Kanagawa (JP); Hiroshi Yamashita, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NED ELECTRONICS CORPORATION, Kawasaki (JP)

(21) Appl. No.: 11/790,081

(22) Filed: Apr. 23, 2007

(30) Foreign Application Priority Data
Apr. 24, 2006 (JP) 2006-118741

(51) Int. Cl. H01L 23/48

(52) U.S. Cl. 257/693

(57) ABSTRACT

A semiconductor module includes a wiring board having a bottom surface and a top surface. A first solder electrode terminal has a given melting point, and is provided on the bottom surface of the wiring board. An electrode pad is provided on or above the top surface of the wiring board, and a second solder electrode terminal is soldered to the electrode pad at a temperature corresponding to the given melting point of the first solder electrode terminal by using a reflow process. The second solder electrode terminal contains an additional metal powder component diffused therein when being soldered to the electrode pad.

### BACKGROUND OF THE INVENTION

1. Field of the Invention

The present invention relates to a semiconductor module including a wiring board, at least one electronic device mounted on a top surface of the wiring board, and a plurality of solder balls as external electrode terminals adhered to a bottom surface of the wiring board, and also relates to a method for manufacturing such a semiconductor module.

2. Description of the Related Art

Recently, various types of semiconductor modules have been developed. For example, there are a flip-chip type, a chip-on-chip (COC) type, a package-on-package (POP) type and so on. Such a semiconductor module includes a wiring board which is called an interposer or a package board, at least one electronic device such as a semiconductor device, a passive element device or the like mounted on a top surface of the wiring board, and a plurality of solder balls as external electrode terminals provided on a bottom surface of the wiring board. Usually, the electronic device has electrode terminals made of a suitable solder material, and the electrode terminals are soldered on electrode pads on or above the wiring board by using a reflow process.

After the semiconductor module is completed, it is mounted on a motherboard so that the solder balls of the wiring board are soldered to electrode pads formed on the mother board by using a reflow process. During this reflow process, the solder electrode terminals of the electronic device should be prevented from being thermally fused (reflowing), because the thermal fusing of the solder electrode terminals may cause disadvantages in the semiconductor module as will be stated in detail hereinafter.

JP-2004-259886 A discloses a structure of a POP type semiconductor module which includes a lower semiconductor package, and an upper semiconductor package mounted on the lower semiconductor package. The lower semiconductor package has a plurality of solder balls provided on a bottom surface thereof, and the upper semiconductor package has a plurality of solder balls provided on a bottom surface thereof and having a higher melting point than that of the solder balls of the lower semiconductor package.

In JP-2004-259886 A, when the upper semiconductor package is mounted on the lower semiconductor package, the solder balls of the upper semiconductor package are soldered to electrode pads formed on the lower semiconductor package, at a high temperature corresponding to the melting point of the solder balls of the upper semiconductor package by using a reflow process to thereby produce the POP type semiconductor module.

When the POP type semiconductor module is mounted on the motherboard, the solder balls of the lower semiconductor package are soldered to electrode pads formed on the motherboard at a low temperature corresponding to the melting point of the solder balls of the lower semiconductor package by using a reflow process. Thus, the soldering of the solder balls of the lower semiconductor package to the electrode pads on the motherboard can be carried out without thermally fusing the solder balls of the upper semiconductor package.

### SUMMARY OF THE INVENTION

It has now been discovered that the above-mentioned prior art semiconductor module has problems to be solved as mentioned hereinbelow.

In JP-2004-259886 A, when more than two semiconductor packages are mounted one after another, more than two reflow processes must be carried out. In this case, it is necessary to prepare various solder materials having different melting points to form solder balls of each of the semiconductor packages before each of the reflow processes can be properly carried out. However, in reality, it is very difficult to prepare the various solder materials having the different melting points.

In accordance with a first aspect of the present invention, there is provided a semiconductor module which includes a wiring board having a bottom surface and a top surface, a first solder electrode terminal having a given melting point and provided on the bottom surface of the wiring board, an electrode pad provided on or above the top surface of the wiring board, and a second solder electrode terminal soldered to the electrode pad at a temperature corresponding to the given melting point of the first solder electrode terminal by using a reflow process. The second solder electrode terminal contains an additional metal powder component diffused therein when being soldered to the electrode pad, whereby a melting point of the second solder electrode terminal becomes higher than the aforesaid given melting point thereof.

The additional metal powder component may have a size or diameter of at most 10 μm, and the size or diameter preferably falls within a range between 2 μm and 10 μm. Also, the additional metal powder component may comprise either gold (Au) or bismuth (Bi).

Preferably, the first solder electrode terminal is composed of the same components as the second solder electrode terminal except for the additional metal powder component.

The semiconductor module may further include an electronic device provided on the top surface of the wiring board. In this case, the electrode pad is formed on the top surface of the wiring board, and the second solder electrode terminal is defined as a solder electrode terminal for the semiconductor device.

The electronic device may be defined as a flip-chip type semiconductor device. In this case, the second solder electrode terminal is defined as a solder bump for the flip-chip type semiconductor device. Also, the additional metal powder component may have a size or diameter of at most 5 μm, and the size or diameter preferably falls within a range between 2 μm and 5 μm.

The electronic device may be defined as a passive element device. In this case, the second solder electrode terminal is defined as a pair of solder electrode terminals for the passive element device. Also, the additional metal powder component may have a size or diameter of at most 10 μm, and the size or diameter preferably falls within a range between 5 μm and 10 μm.

The semiconductor module may further include a semiconductor device provided on the top surface of the wiring board, and a flip-chip type semiconductor device provided on the first semiconductor device. In this case, the electrode pad is formed on the first semiconductor device, and the second solder electrode terminal is defined as a solder bump for the flip-chip type semiconductor device. Also, the additional metal powder component may have a size or diameter of at most 5 μm, and the size or diameter preferably falls within a range between 2 μm and 5 μm.

The semiconductor module may further include a semiconductor package provided on the top surface of the wiring board. In this case, the electrode pad is formed on the top surface of the wiring board, and the second solder electrode terminal is defined as an external solder electrode terminal for the semiconductor package. Also, the additional metal powder component has a size or diameter of at most 10 μm, and the size or diameter preferably falls within a range between 5 μm and 10 μm.

In accordance with a second aspect of the present invention, there is provided a semiconductor module which includes a wiring board, a first solder electrode terminal having a given melting point and provided oh a bottom surface of the wiring board, an electrode pad (10A in FIG. 3) provided on the bottom surface of the wiring board, and a second solder electrode terminal soldered to the electrode pad at a temperature corresponding to the given melting point of the first solder electrode terminal by using a reflow process. The second solder electrode terminal contains an additional metal powder component diffused therein when being soldered to the electrode pad, whereby a melting point of the second solder electrode terminal becomes higher than the aforesaid given melting point thereof.

In the second aspect of the present invention, the semiconductor module may further include an electronic device provided on the bottom surface of the wiring board, and the second solder electrode terminal is defined as a solder electrode terminal for the electronic device.

In accordance with a third aspect of the present invention, there is provided a method for manufacturing a semiconductor module, which includes: preparing a wiring board having a bottom surface and a top surface; providing a first solder electrode terminal having a given melting point on the bottom surface of the wiring board; providing an electrode pad on or above the top surface of the wiring board; soldering a second solder electrode terminal to the electrode pad at a temperature corresponding to the given melting point of the first solder electrode terminal by using a reflow process; and diffusing an additional metal powder component in the second solder electrode terminal when the second solder electrode terminal is soldered to the electrode pad, whereby a melting point of the second solder electrode terminal becomes higher than the aforesaid given melting point thereof.

The diffusing of the additional metal powder component in the second solder electrode terminal may be carried out by previously depositing a metal paste on the electrode pad before the second solder electrode terminal is soldered to the electrode pad. Alternatively, the diffusing of the additional metal powder component in the second solder electrode terminal may be carried out by previously applying a metal paste to the second solder electrode terminal before the second solder electrode terminal is soldered to the electrode pad.

In the method, the additional metal powder component may have a size or diameter of at most 10 μm, and the size or diameter preferably falls within a range between 2 μm and 10 μm. Also, the additional metal powder component may include either gold (Au) or bismuth (Bi).

### BRIEF DESCRIPTION OF THE DRAWINGS

The present invention will be more clearly understood from the description set forth below, with reference to the accompanying drawings, wherein:

FIGS. 1A to 1G are cross-sectional views for explaining a first embodiment of the method for manufacturing the semiconductor module according to the present invention;

FIG. 2A is a cross-sectional view, corresponding to FIG. 1B, for explaining a modification of the first embodiment of the method of FIGS. 1A to 1G;

FIG. 2B is a cross-sectional view, corresponding to FIG. 1D, for explaining another modification of the first embodiment of the method of FIGS. 1A to 1G;

FIG. 3 is a cross-sectional view, corresponding to FIG. 1G, for explaining yet another modification of the first embodiment of the method of FIGS. 1A to 1G;

FIG. 4A is an elevation view, corresponding to FIG. 1G, for explaining disadvantages which are suffered when the semiconductor module is not manufactured according to the present invention;

FIG. 4B is another elevation view, corresponding to FIG. 1G, for explaining disadvantages which are suffered when the semiconductor module is not manufactured according to the present invention;

FIG. 5A is an elevation view, corresponding to FIG. 3, for explaining disadvantages which are suffered when the semiconductor module is not manufactured according to the present invention;

FIG. 5B is another elevation view, corresponding to FIG. 3, for explaining disadvantages which are suffered when the semiconductor module is not manufactured according to the present invention;

FIG. 6A is an enlarged cross-sectional view, corresponding to FIG. 1G, for explaining disadvantages which are suffered when the semiconductor module is not manufactured according to the present invention;

FIG. 6B is an enlarged cross-sectional view similar to FIG. 6A;

FIG. 7A is another enlarged cross-sectional view, corresponding to FIG. 1G, for explaining disadvantages which are suffered when the semiconductor module is not manufactured according to the present invention;

FIG. 7B is an enlarged cross-sectional view similar to FIG. 7A;

FIG. 8A is yet another enlarged cross-sectional view, corresponding to FIG. 1G, for explaining disadvantages which are suffered when the semiconductor module is not manufactured according to the present invention;

FIG. 8B is an enlarged cross-sectional view similar to FIG. 8A;

FIGS. 9A to 9F are cross-sectional views for explaining a second embodiment of the method for manufacturing the semiconductor module according to the present invention;

FIGS. 10A to 10D are cross-sectional views for explaining a third embodiment of the method for manufacturing the semiconductor module according to the present invention;

FIGS. 11A to 11D are cross-sectional views for explaining a fourth embodiment of the method for manufacturing the semiconductor module according to the present invention;

FIGS. 12A to 12E are cross-sectional views for explaining a fifth embodiment of the method for manufacturing the semiconductor module according to the present invention;

FIG. 13A is an enlarged cross-sectional view of a passive element device included in the semiconductor module of FIG. 12E, for explaining disadvantages which are suffered when the semiconductor module is not manufactured according to the present invention;

FIG. 13B is an enlarged cross-sectional view similar to FIG. 13A;

FIG. 14A is an enlarged cross-sectional view of a passive element device included in the semiconductor module of FIG. 12E, for explaining disadvantages which are suffered when the semiconductor module is not manufactured according to the present invention;

FIG. 14B is an enlarged cross-sectional view similar to FIG. 14A;

FIG. 15A is an enlarged cross-sectional view of a passive element device included in the semiconductor module of FIG. 12E, for explaining disadvantages which are suffered when the semiconductor module is not manufactured according to the present invention; and

FIG. 15B is an enlarged cross-sectional view similar to FIG. 15A.

### DESCRIPTION OF THE PREFERRED EMBODIMENTS

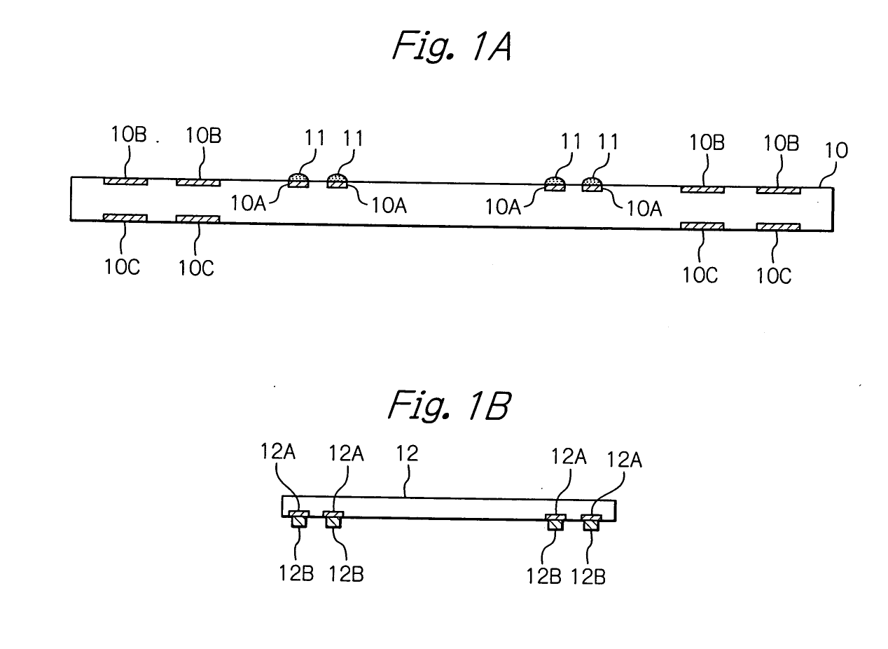

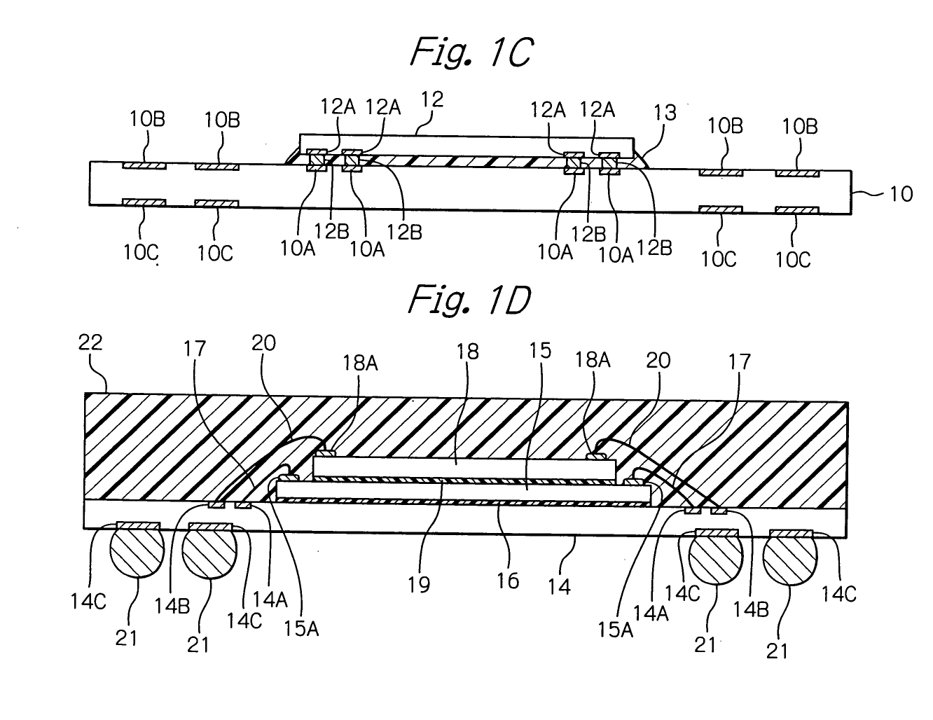

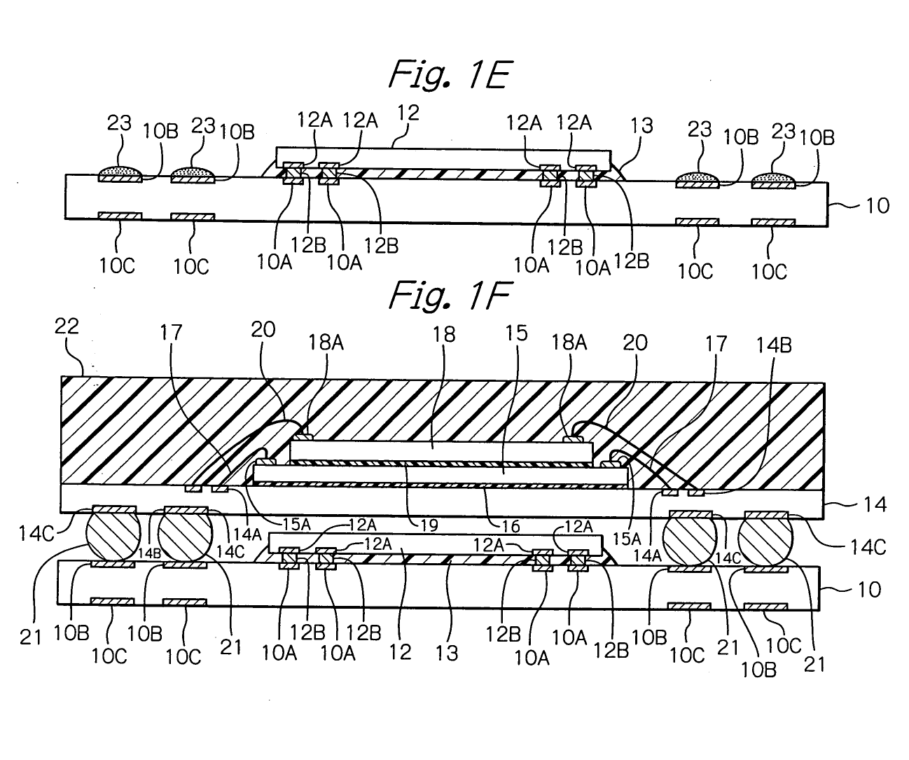

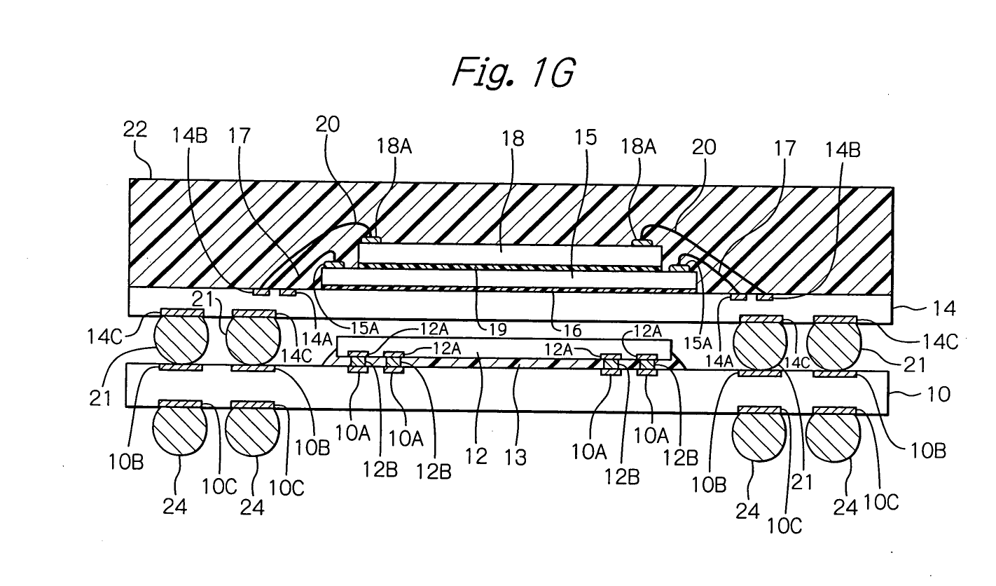

With reference to FIGS. 1A to 1G which are partial cross-sectional views, a first embodiment of a method for manufacturing a semiconductor module according to the present invention will now be explained below.

First, referring to FIG. 1A, a wiring board 10, which is called an interposer or a package board, is prepared. The wiring board 10 has a plurality of electrode pads 10A and 10B formed on a top surface thereof, and a plurality of electrode pads 10C formed on a bottom surface thereof. A piece of metal paste 11, which is composed of a flux solution component and a metal powder component, is deposited on each of the electrode pads 10A by using a silk printing process.

Note that the metal powder component may be gold (Au), bismuth (Bi) or the like. Also, note that the metal powder component features a size or diameter of at most 5 μm, and the size or diameter preferably falls within a range between 2 μm and 5 μm.

On the other hand, referring to FIG. 1B, a flip-chip type semiconductor chip 12 is prepared. The flip-chip type semiconductor chip 12 has a plurality of electrode pads 12A formed on a front face thereof, and a plurality of solder bumps 12B soldered to the electrode pads 12A, with each of the solder bumps 12B serving as an electrode terminal. Note that the solder bumps 12B have a predetermined melting point.

Next, referring to FIG. 1C, the flip-chip type semiconductor chip 12 is mounted on the wiring board 10 such that the solder bumps 12B are rested on the respective electrode pads 10A with the pieces of metal paste 11 (see: FIG. 1A), and then are subjected to a reflow process in which the solder bumps 12B are soldered to the respective electrode pads 10A on the top surface of the wiring board 10.

In particular, in the reflow process, both the wiring board 10 and the flip-chip type semiconductor device 12 are exposed to a hot air stream which is heated to the melting point of the solder bumps 12B so that the solder bumps 12B are thermally fused, and then are exposed to a cool air stream so that the fused solder bumps 12B are set, resulting in completion of the soldering of the solder bumps 12B to the respective electrode pads 10A on the top surface of the wiring board 10.

When each of the solder bumps 12B is thermally fused in the reflow process, the metal powder component contained in each of the pieces of metal paste 11 (see: FIG. 1A) is diffused as an additional metal component in the fused solder bump 12B concerned, so that the set solder bumps 12B exhibits a higher melting point than the original melting point thereof. In short, the melting point of the solder bumps 12B becomes higher due to the diffusion of the metal powder component in the solder bumps 12B.

After the soldering of the solder bumps 12B to the electrode pads 10A on the top surface of the wiring board 10 is completed, the flip-chip type semiconductor device 12 is subjected to an underfilling process in which a suitable resin material is introduced into a space between the wiring board 10 and the flip-chip type semiconductor device 12 to thereby form a sealing resin layer 13 therebetween. Namely, the electrode pads 10A, the electrode pads 12A and the solder bumps 12B are sealed and protected by the sealing resin layer 13, resulting in completion of production of a semiconductor package including the wiring board or interposer 10, the flip-chip type semiconductor chip 12 and the sealing resin layer 13 as shown in FIG. 1C.

On the other hand, referring to FIG. 1D, a chip-on-chip (COC) type semiconductor package is prepared, and includes a wiring board 14 which is called an interposer or a package board. The wiring board 14 has a plurality of electrode pads 14A and 14B formed on a top surface thereof, and a plurality of electrode pads 14C formed on a bottom surface thereof.

The COC type semiconductor package of FIG. 1D is provided with a semiconductor device (chip) 15 mounted on the wiring board 14 in such a manner that a rear face of the semiconductor device 15 is adhered to the top surface of the wiring board 14 by using a suitable adhesive layer 16. The semiconductor device 15 has a plurality of electrode pads 15A formed on a front face thereof, and each of the electrode pads 15A is electrically connected to any one of the electrode pads 14B on the wiring board 14 by a bonding wire 17, using a wire bonding machine (not shown).

The COC type semiconductor package of FIG. 1D is also provided with a semiconductor device (chip) 18 mounted on the semiconductor device 15 in such a manner that a rear face of the semiconductor device 18 is adhered to the front face of the semiconductor device 15 by using a suitable adhesive layer 19. The semiconductor device 18 has a plurality of electrode pads 18A formed on a front face thereof, and each of the electrode pads 18A is electrically connected to any one of the electrode pads 14B on the wiring board 14 by a bonding wire 20, using a wire bonding machine (not shown).

The COC type semiconductor package of FIG. 1D is further provided with a plurality of solder balls 21 which are soldered as external electrode terminals to the respective electrode pads 14C on the bottom surface of the wiring board 14, and each of the solder balls 21 serves as an external electrode terminal.

Note that the solder balls 21 are formed of the same solder material as that used for the solder bumps 12B of the flip-chip type semiconductor chip 12 (see: FIG. 1B), so that the solder balls 21 have the same melting point as the original melting point of the solder bumps 12B in which the metal powder component such as gold (A), bismuth (Bi) or the like is not diffused.

The COC type semiconductor package of FIG. 1D also includes a sealing resin layer 22 which is formed on the top surface of the wiring board 14 so that the electrode pads 14A and 14B, the semiconductor devices 15 and 18, the bonding wires 17 and 20 and so on are sealed in the sealing resin layer 22. Note that it is possible to carry out the formation of the sealing resin layer 22 by using a transfer molding process. Also, note that the COC type semiconductor package of FIG. 1D may be called a ball grid array (BGA) type semiconductor package.

Next, referring to FIG. 1E, a piece of metal paste 23, which is composed of a flux solution component and a metal powder component, is deposited on each of the electrode pads 10B of the wiring board 10 by using a silk printing process. Similar to the pieces of metal paste 11 (see: FIG. 1A), although the metal powder component contained in the pieces of metal paste 23 may be gold (Au), bismuth (Bi) or the like, it features a size or diameter of at most 10 μm. Preferably, the size or diameter preferably falls within a range between 5 μm and 10 μm.

Next, referring to FIG. 1F, the semiconductor package of FIG. 1D is mounted on the wiring board 10 such that the solder balls 21 are rested on the respective electrode pads 10B with the pieces of metal paste 23 (see: FIG. 1E), and then are subjected to a reflow process in which the solder balls 21 are soldered to the respective electrode pads 10B on the top surface of the wiring board 10.

In particular, in the reflow process, both the semiconductor package of FIG. 1D and the semiconductor package of FIG. 1E are exposed to a hot air stream which is heated to the melting point of the solder balls 21 so that the solder balls 21 are thermally fused, and then are exposed to a cool air stream so that the fused solder balls 21 are set, resulting in completion of the soldering of the solder balls 21 to the respective electrode pads 10B on the top surface of the wiring board 10.

At this time, the soldering of the solder balls 21 to the respective electrode pads 10B can be carried out without thermally fusing the solder bumps 12B of the flip-chip type semiconductor device 12, because the melting point of the solder bumps 12B is higher than the original melting point thereof due to the diffusion of the metal powder component in the solder bumps 12B, as stated above.

When each of the solder balls 21 is thermally fused in the reflow process, the metal powder component contained in each of the pieces of metal paste 23 (see: FIG. 1E) is diffused as an additional metal component in the fused solder ball 21 concerned, so that the set solder balls 21 exhibit a higher melting point than the original melting point thereof. In short, similar to the solder bumps 12B of the flip-chip type semiconductor device 12, the melting point of the solder balls 21 becomes higher due to the diffusion of the metal powder component in the solder balls 21.

Next, referring to FIG. 1G, after the soldering of the solder balls 21 to the electrode pads 10B is completed, a plurality of solder balls 24 are soldered as external electrode terminals to the respective electrode pads 10C on the bottom surface of the wiring board 10, resulting in completion of a production of a semiconductor module as a package-on-package (POP) type semiconductor package including the two semiconductor packages of FIGS. 1C and 1D.

Note that the solder balls 24 are also formed of the same solder material as that used for the solder bumps 12B of the flip-chip type semiconductor chip 12 (see: FIG. 1B), so that the solder balls 24 have the same melting point as the original melting points of the solder bumps 12B and the solder balls 21 in which the metal powder component such as gold (A), bismuth (Bi) or the like is not diffused.

When the semiconductor module of FIG. 1G is mounted on a motherboard (not shown), it is subjected to a reflow process in which the respective solder balls 24 are soldered on electrode pads formed on the motherboard.

Namely, in the reflow process, the semiconductor module of FIG. 1G is exposed to a hot air stream which is heated to the melting point of the solder balls 24, so that the solder balls 24 are thermally fused, and then are exposed to a cool air stream so that the fused solder balls 24 are set, resulting in completion of the soldering of the solder balls 24 to the respective electrode pads on the motherboard (not shown).

At this time, it is possible to carry out the soldering of the solder balls 24 to the respective electrode pads on the motherboard (not shown) without thermally fusing the solder bumps 12B and the solder balls 21, because the melting points of the solder bumps 12B and the solder balls 21 are higher than the melting point of the solder balls 24 due to the diffusion of the metal powder component in the solder bumps 12B and the solder balls 21, as stated above.

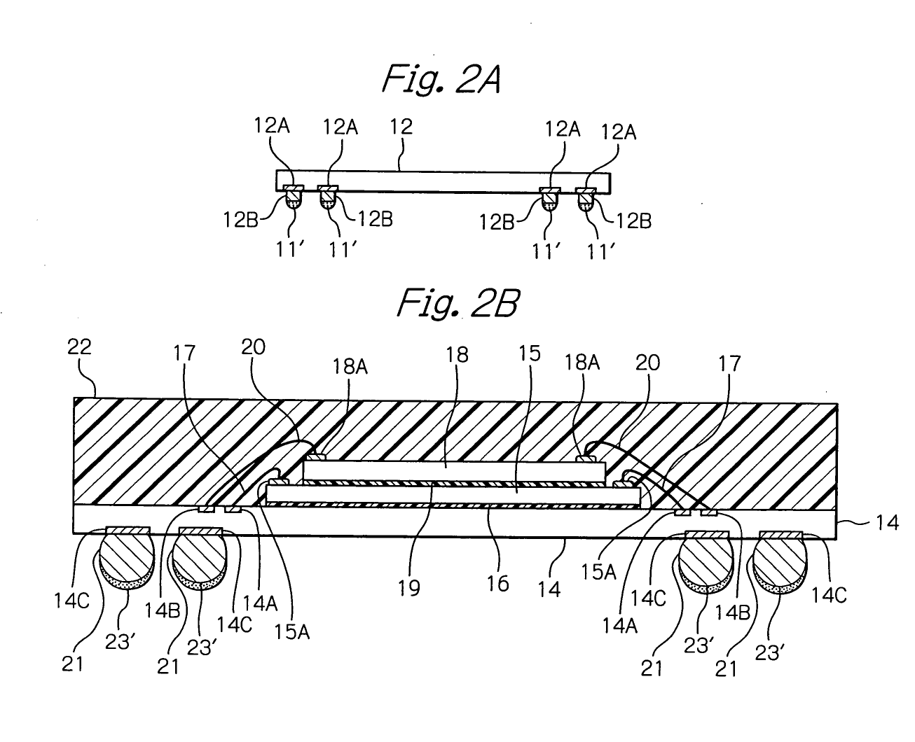

In the above-mentioned first embodiment of FIGS. 1A to 1G, as shown in FIG. 2A which corresponds to FIG. 1B, a piece of metal paste 11′ may be applied to a free end face of each of the solder bumps 12B of the flip-chip type semiconductor device 12 as a substitute for the piece of metal paste 11 deposited on each of the electrode pads 10A on the top surface of the wiring board 10 (see: FIG. 1A).

Similar to the piece of metal paste 11, the piece of metal paste 11′ is composed of a flux solution component and a metal powder component such as gold (Au), bismuth (Bi) or the like, and the metal powder component features a size or diameter of at most 5 μm. Preferably, the size or diameter preferably falls within a range between 2 μm and 5 μm.

When the solder bumps 12B are thermally fused in the reflow process, the metal powder component contained in each of the pieces of metal paste 11′ is diffused as an additional metal component in the fused solder bump 12B concerned, so that the set solder bumps 12B exhibit a higher melting point than the original melting point thereof.

Also, in the above-mentioned first embodiment of FIGS. 1A to 1G, as shown in FIG. 2B which corresponds to FIG. 1D, a piece of metal paste 23′ may be applied to each of the solder balls 21 of the wiring board 14 as a substitute for the piece of metal paste 23 deposited on each of the electrode pads 10B on the top surface of the wiring board 10 (see: FIG. 1E).

Similar to the piece of metal paste 23, the piece of metal paste 23′ is composed of a flux solution component and a metal powder component such as gold (Au), bismuth (Bi) or the like, and the metal powder component features a size or diameter of at most 10 μm. Preferably, the size or diameter falls within a range between 5 μm and 10 μm.

When the solder balls 21 are thermally fused in the reflow process, the metal powder component contained in each of the pieces of metal paste 23′ is diffused as an additional metal component in the fused solder balls 21 concerned, so that the set solder balls 21 exhibit a higher melting point than the original melting point thereof.

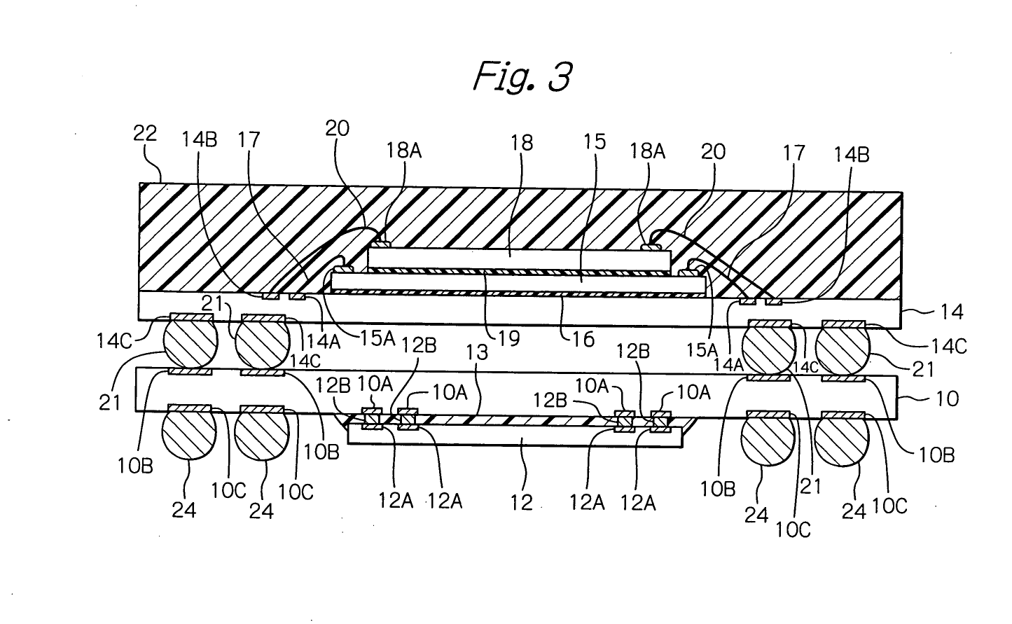

Further, in the above-mentioned first embodiment of FIGS. 1A to 1G, as shown in FIG. 3 which corresponds to FIG. 1G, the flip-chip type semiconductor device 12 may be provided on the bottom surface of the wiring board 10.

Furthermore, in the above-mentioned first embodiment of FIGS. 1A to 1G, although not illustrated in FIG. 1G, other solder balls (21) may be provided between the wiring boards 10 and 14 so as to surround the flip-chip type semiconductor device 12. Similarly, although not illustrated in FIG. 3, other solder balls (21) may be provided between the wiring boards 10 and 14.

If the semiconductor module of FIG. 1G or FIG. 3 is mounted on a motherboard (not shown) by using a reflow process, and if the solder balls 21 have a melting point which is equivalent to that of the solder balls 24, the semiconductor module of. FIG. 1G or FIG. 3 may suffer disadvantages due to the fact that the wiring board 10 is warped during the reflow process, as will be stated below.

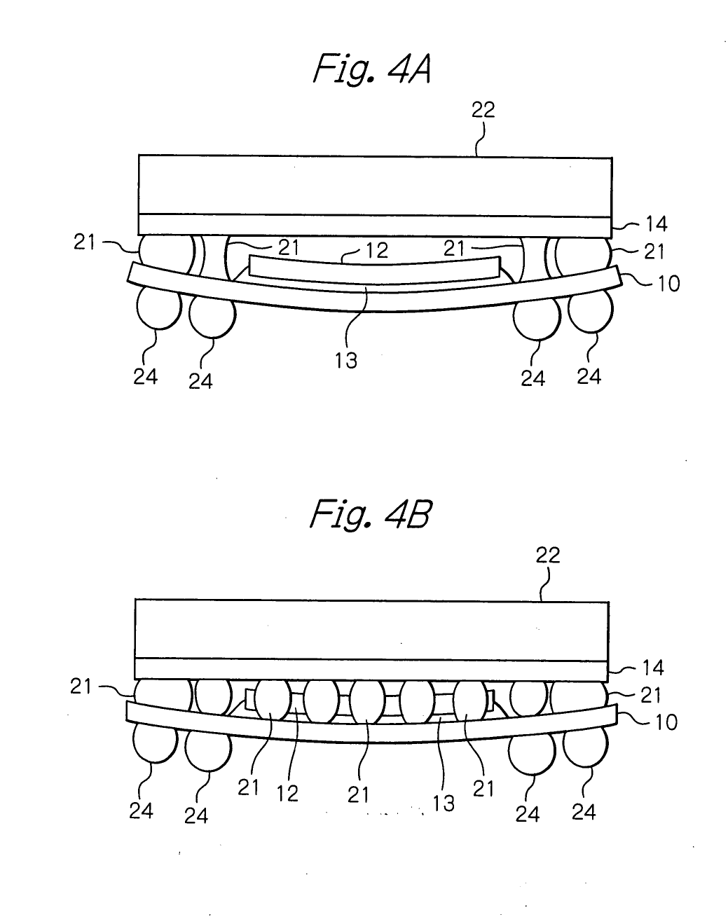

First, referring to FIG. 4A which is a schematic elevation view corresponding to FIG. 1G, during the reflow process, the wiring board 10 is warped so that a middle of the wiring board 10 recedes away from the wiring board 14, because the wiring board 10 has a larger coefficient of thermal expansion than that of the flip-chip type semiconductor device 12. In this case, if the solder balls 21 have the melting point which is equivalent to that of the solder balls 24, they are thermally fused and deformed due to the warpage of the wiring board 10. Thus, the semiconductor module of FIG. 4A suffers disadvantages that short circuits may occur among the deformed solder balls 21.

Next, referring to FIG. 4B which is a schematic elevation view similar to FIG. 4A, a plurality of solder balls 21 may be further provided between the wiring boards 10 and 14 so as to surround the flip-chip type semiconductor device 12. In this case, the semiconductor module of FIG. 4B also suffers similar disadvantages to those of the semiconductor module of FIG. 4A.

Nevertheless, in reality, the semiconductor module of FIG. 1G is free from the aforesaid disadvantages because the solder balls 21 cannot be thermally fused and deformed when the semiconductor module of FIG. 1G is mounted on the motherboard by using the reflow process.

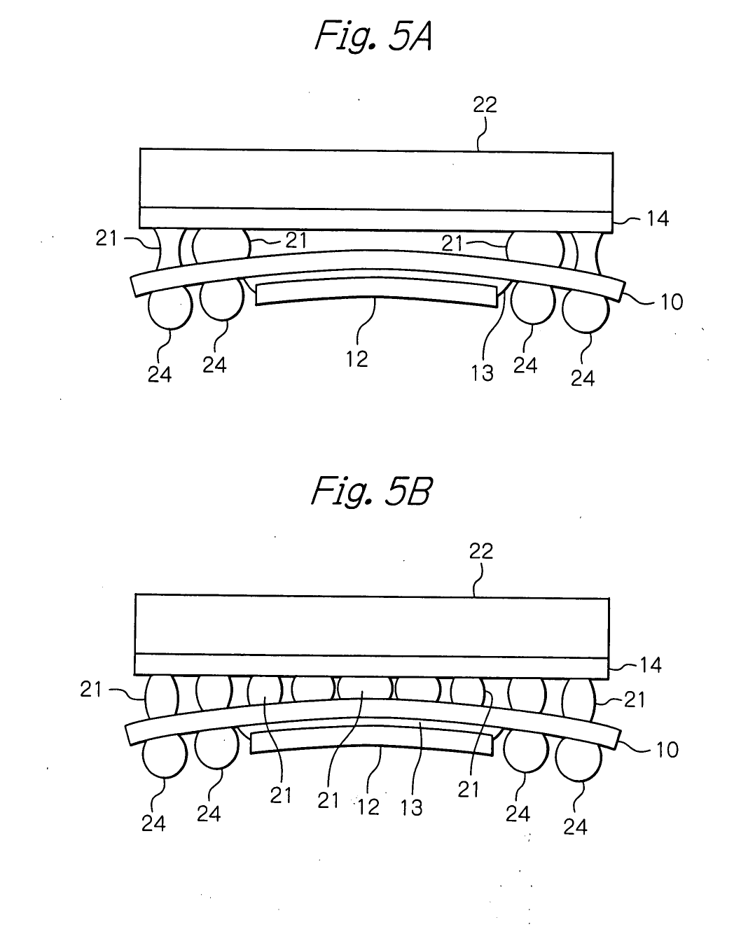

On the other hand, referring to FIG. 5A which is a schematic elevation view corresponding to FIG. 3, during the reflow process, the wiring board 10 is warped so that a middle of the wiring board 10 proceeds toward the wiring board 14 for the same reason as stated above. In this case, if the solder balls 21 have the melting point which is equivalent to that of the solder balls 24, they are thermally fused and deformed due to the warpage of the wiring board 10. Thus, the semiconductor module of FIG. 5A suffers disadvantages that short circuits may occur among the deformed solder balls 21.

Next, referring to FIG. 5B which is a schematic elevation view similar to FIG. 5A, a plurality of solder balls 21 may be further provided between the wiring boards 10 and 14. In this case, the semiconductor module of FIG. 5B also suffers more strict disadvantages in comparison with the semiconductor module of FIG. 5A because the space between the wiring boards 10 and 14 becomes narrower at the middle thereof.

Nevertheless, in reality, the semiconductor module of FIG. 3 is also free from the aforesaid disadvantages because the solder balls 21 cannot be thermally fused and deformed when the semiconductor module of FIG. 3 is mounted on the motherboard by using the reflow process.

In addition, if the semiconductor module of FIG. 1G is mounted on a motherboard (not shown) by using a reflow process, and if the solder bumps 12B of the flip-chip type semiconductor 12 have the melting point which is equivalent to that of the solder balls 24, the semiconductor module of FIG. 1G may suffer disadvantages due to the fact that a fine void and a fine clearance are apt to be defined in the seal resin layer 13, as will be stated below.

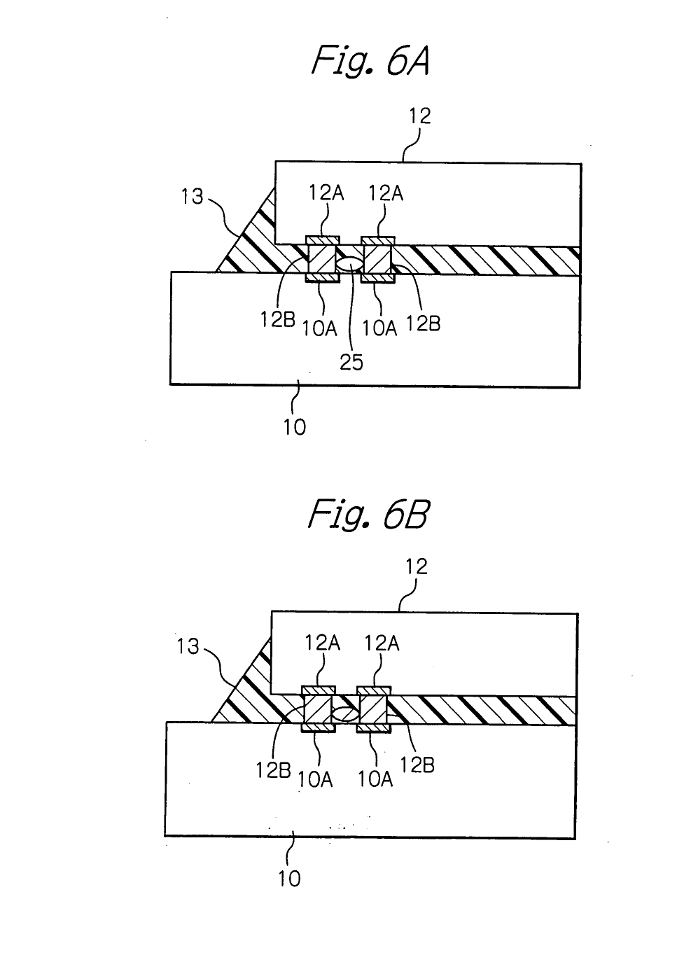

First, referring to FIG. 6A which is a partially-enlarged cross-sectional view of FIG. 1G, the electrode pads 10A, the electrode pads 12A and the solder bumps 12B are sealed by the sealing resin layer 13, but a fine void 25 may be defined in the seal resin layer 20 between the adjacent solder bumps 12B.

Next, referring to FIG. 6B which is similar to FIG. 6A, during the reflow process of the solder balls 24 (see: FIG. 1G), the solder bumps 12B are thermally fused so that the fused solder may penetrate into the void 25 due to a capillary phenomenon, resulting in occurrence of a short circuit between the solder bumps 12B.

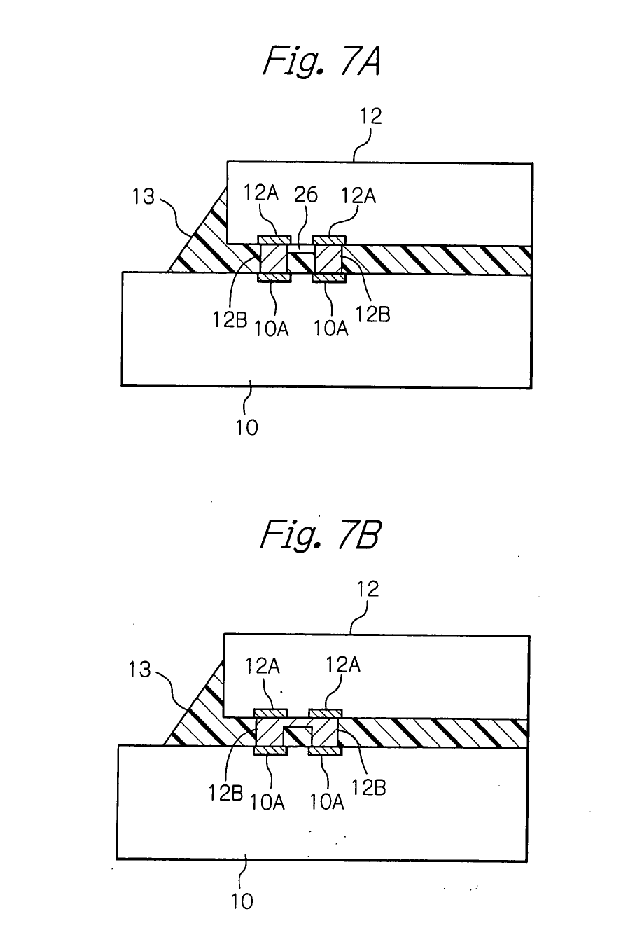

Also, referring to FIG. 7A which is a partially-enlarged cross-sectional view of FIG. 1G, the electrode pads 10A, the electrode pads 12A and the solder bumps 12B are sealed by the sealing resin layer 13, but a fine clearance 26 may be defined in the seal resin layer 20 beneath the front face of the flip-chip type semiconductor device 12 between the adjacent solder bumps 12B.

Next, referring to FIG. 7B which is similar to FIG. 7A, during the reflow process of the solder balls 24 (see: FIG. 1G), the solder bumps 12B are thermally fused so that the fused solder may penetrate into the fine clearance 26 due to a capillary phenomenon, resulting in occurrence of a short circuit between the solder bumps 12B.

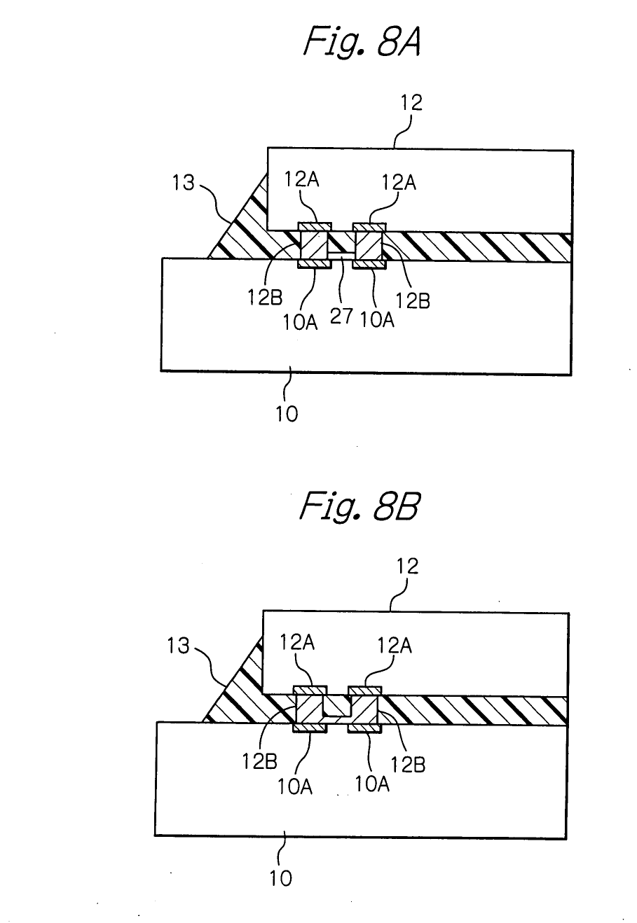

Further, referring to FIG. 8A which is a partially-enlarged cross-sectional view of FIG. 1G, the electrode pads 1A, the electrode pads 12A and the solder bumps 12B are sealed by the sealing resin layer 13, but a fine clearance 27 may be defined in the seal resin layer 20 above the top surface of the wiring board 10 between the adjacent solder bumps 12B.

Next, referring to FIG. 8B which is similar to FIG. 8A, during the reflow process of the solder balls 24 (see: FIG. 1G), the solder bumps 12B are thermally fused so that the fused solder may penetrate into the fine clearance 27 due to a capillary phenomenon, resulting in occurrence of a short circuit between the solder bumps 12B.

Note that the semiconductor module of FIG. 3 also may suffer the disadvantages as explained with reference to FIGS. 6A and 6B, FIGS. 7A and 7B and FIGS. 8A and 8B as long as the solder bumps 12B of the flip-chip type semiconductor 12 have the melting point which is equivalent to that of the solder balls 24.

Nevertheless, the semiconductor module of FIG. 1G or FIG. 3 is free from the aforesaid disadvantages because the metal bumps 12B cannot be thermally fused when the semiconductor module concerned is mounted on the motherboard (not shown) by using the reflow process.

### Second Embodiment

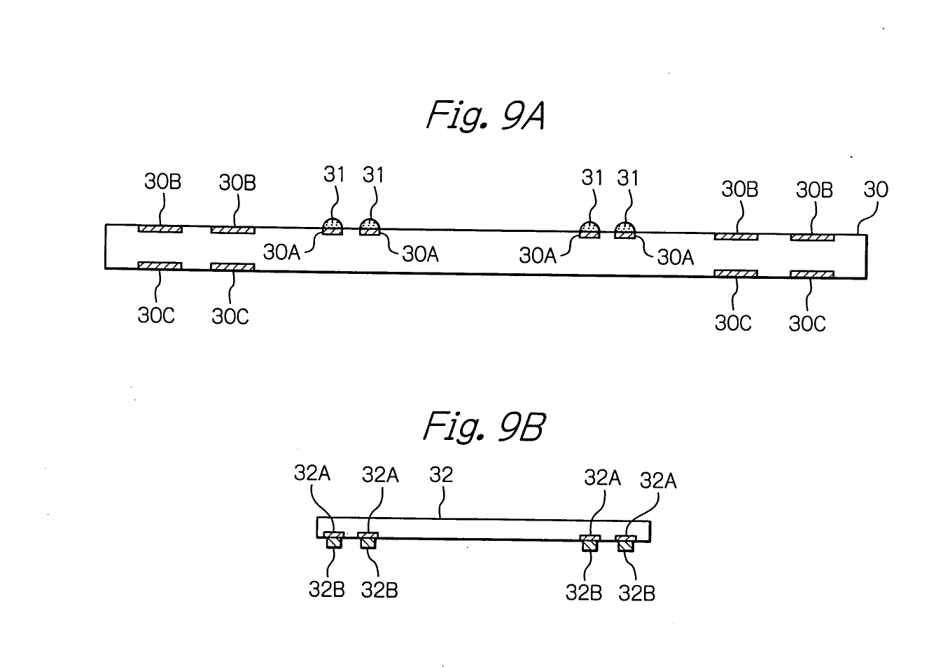

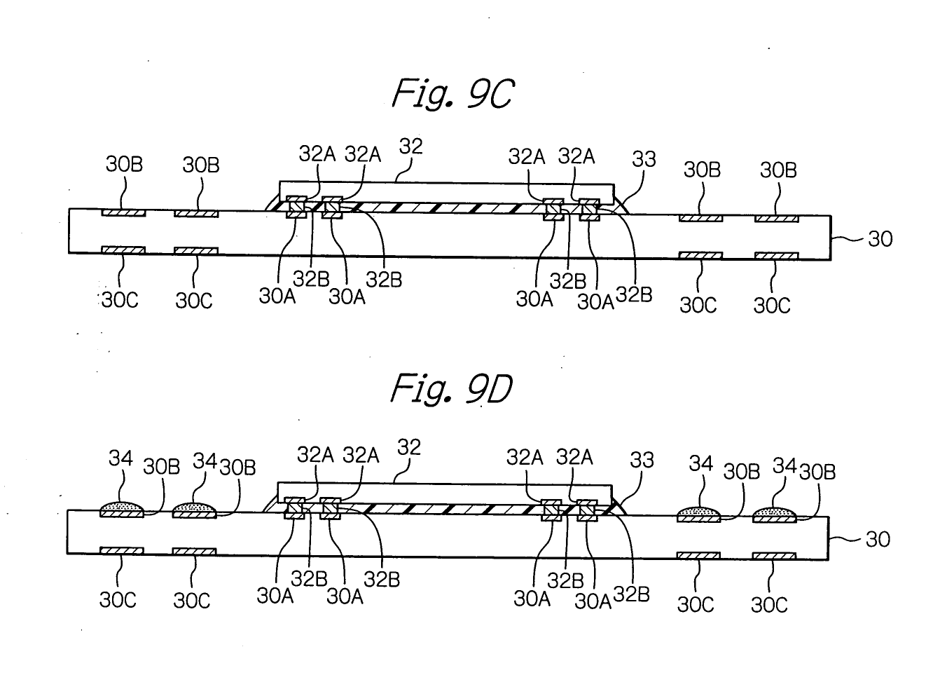

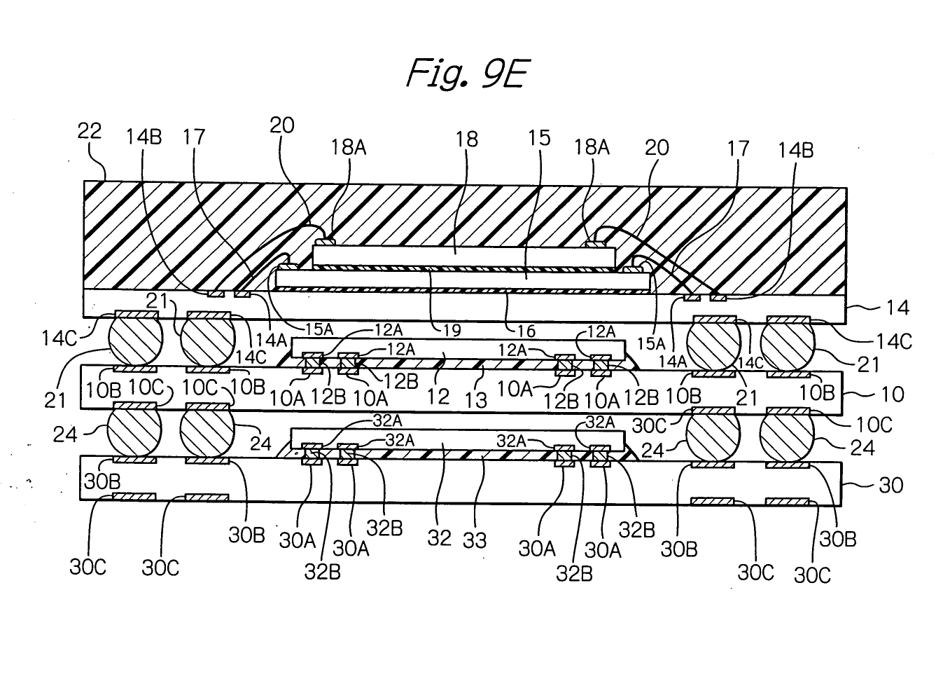

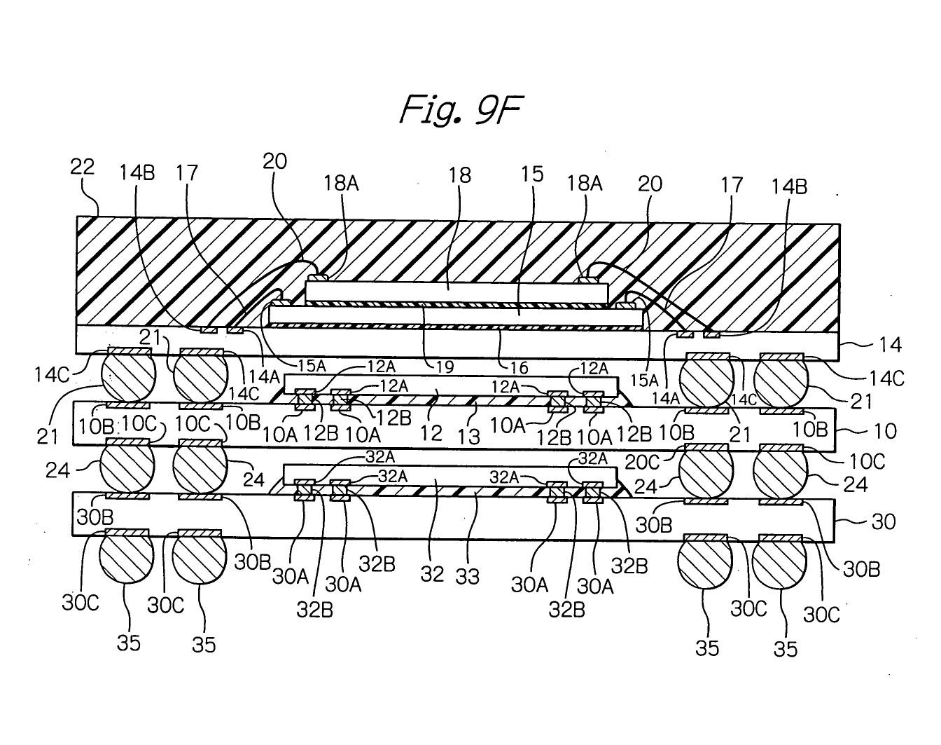

With reference to FIGS. 9A to 9F, a second embodiment of the method for manufacturing the semiconductor module according to the present invention is explained below.

Note, in the second embodiment, the semiconductor module of FIG. 1G is further processed.

First, referring to FIG. 9A, a wiring board 30, which is called an interposer or a package board, is prepared. The wiring board 30 has a plurality of electrode pads 30A and 30B formed on a top surface thereof, and a plurality of electrode pads 30C formed on a bottom surface thereof. A piece of metal paste 31, which is composed of a flux solution component and a metal powder component, is deposited on each of the electrode pads 30A by using a silk printing process.

Note that the piece of metal paste 31 is substantially the same as the piece of metal paste 11 (FIG. 1A). Namely, the metal powder component may be gold (Au), bismuth (Bi) or the like, and features a size or diameter of at most 5 μm. Preferably, the size or diameter falls within a range between 2 μm and 5 μm.

On the other hand, referring to FIG. 9B, a flip-chip type semiconductor chip 32 is prepared. The flip-chip type semiconductor chip 32 has a plurality of electrode pads 32A formed on a front face thereof, and a plurality of solder bumps 32B soldered to the electrode pads 32A, with each of the solder bumps 32B serving as an electrode terminal. Note that the solder bumps 32B have substantially the same melting point as that of the solder bumps 12B (see: FIG. 1B).

Next, referring to FIG. 9C, the flip-chip type semiconductor chip 32 is mounted on the wiring board 30 such that the solder bumps 32B are rested on the respective electrode pads 30A with the pieces of metal paste 31 (see: FIG. 9A), and then are subjected to a reflow process in which the solder bumps 32B are soldered to the respective electrode pads 30A on the top surface of the wiring board 30.

In particular, in the reflow process, both the wiring board 30 and the flip-chip type semiconductor device 32 are exposed to a hot air stream which is heated to the melting point of the solder bumps 32B so that the solder bumps 32B are thermally fused, and then are exposed to a cool air stream so that the fused solder bumps 32B are set, resulting in completion of the soldering of the solder bumps 32B to the respective electrode pads 30A on the top surface of the wiring board 30.

Similar to the case explained with reference to FIG. 1C, when each of the solder bumps 32B is thermally fused in the reflow process, the metal powder component contained in each of the pieces of metal paste 31 (FIG. 9A) is diffused as an additional metal component in the fused solder bump 32B concerned, so that the set solder bumps 32B exhibit a higher melting point than the original melting point thereof. In short, the melting point of the solder bumps 32B becomes higher due to the diffusion of the metal powder component in the solder bumps 32B.

After the soldering of the solder bumps 32B to the electrode pads 30A on the top surface of the wiring board 30 is completed, the flip-chip type semiconductor device 32 is subjected to an underfilling process in which a suitable resin material is introduced into a space between the wiring board 30 and the flip-chip type semiconductor device 32 to thereby form a sealing resin layer 33 therebetween. Namely, the electrode pads 30A, the electrode pads 32A and the solder bumps 32B are sealed and protected by the sealing resin layer 33, resulting in completion of production of a semiconductor package including the wiring board or interposer 30, the flip-chip type semiconductor chip 32 and the sealing resin layer 33 as shown in FIG. 9C.

Next, referring to FIG. 9D, a piece of metal paste 34, which is composed of a flux solution component and a metal powder component, is deposited on each of the electrode pads 30B of the wiring board 30 by using a silk printing process.

Note that the piece of metal paste 34 is substantially the same as the piece of metal paste 23 (FIG. 1E). Namely, the metal powder component may be gold (Au), bismuth (Bi) or the like, and features a size or diameter of at most 10 μm. Preferably, the size or diameter falls within the range between 5 μm and 10 μm.

Next, referring to FIG. 9E, the semiconductor package of FIG. 1G is mounted on the wiring board 30 such that the solder balls 24 are rested on the respective electrode pads 30B with the pieces of metal paste 34 (see: FIG. 9D), and then are subjected to a reflow process in which the solder balls 24 are soldered to the respective electrode pads 30B on the top surface of the wiring board 30.

In particular, in the reflow process, both the semiconductor module of FIG. 1G and the semiconductor package of FIG. 9D are exposed to a hot air stream which is heated to the melting point of the solder balls 24 so that the solder balls 24 are thermally fused, and then are exposed to a cool air stream so that the fused solder balls 24 are set, resulting in completion of the soldering of the solder balls 24 to the respective electrode pads 30B on the top surface of the wiring board 30.

At this time, the soldering of the solder balls 24 to the respective electrode pads 30B can be carried out without thermally fusing the solder bumps 12B, the solder balls 21 and the solder bumps 32B, because the melting point of the solder bumps 12B, the solder balls 21 and the solder bumps 32B is higher than the original melting points thereof due to the diffusion of the metal powder component in the solder bumps 12B, the solder balls 21 and the solder bumps 32B, as stated above.

When each of the solder balls 24 is thermally fused in the reflow process, the metal powder component contained in each of the pieces of metal paste 34 (see: FIG. 9D) is diffused as an additional metal component in the fused solder ball 24 concerned, so that the set solder balls 24 exhibit a higher melting point than the original melting point thereof. In short, similar to the solder bumps 12B, the solder balls 21 and the solder bumps 32B, the melting point of the solder balls 24 becomes higher due to the diffusion of the metal powder component in the solder balls 24.

Next, referring to FIG. 9F, after the soldering of the solder balls 24 to the electrode pads 30B is completed, a plurality of solder balls 35 are soldered as external electrode terminals to the respective electrode pads 30C on the bottom surface of the wiring board 30, resulting in completion of a production of a semiconductor module as a POP type semiconductor package including the three semiconductor packages of FIGS. 1C, 1D and 9D.

Note that the solder balls 35 are also formed of the same solder material as that used for the solder bumps 12B, the solder balls 21, the solder balls 24 and the solder bumps 32B, so that the solder balls 35 have the same melting point as the original melting points of the solder bumps 12B, the solder balls 21, the solder balls 24 and the solder bumps 32B in which the metal powder component such as gold (A), bismuth (Bi) or the like is not diffused.

When the semiconductor module of FIG. 9F is mounted on a motherboard (not shown), it is subjected to a reflow process in which the respective solder balls 35 are soldered on electrode pads formed on the motherboard.

Namely, in the reflow process, the semiconductor module of FIG. 9F is exposed to a hot air stream which is heated to the melting point of the solder balls 35, so that the solder balls 35 are thermally fused, and then are exposed to a cool air stream so that the fused solder balls 35 are set, resulting in completion of the soldering of the solder balls 35 to the respective electrode pads on the motherboard (not shown).

At this time, it is possible to carry out the soldering of the solder balls 35 to the respective electrode pads on the motherboard (not shown) without thermally fusing the solder bumps 12B, the solder balls 21, the solder balls 24 and the solder bumps 32B, because the melting points of the solder bumps 12B, the solder balls 21, the solder balls 24 and the solder bumps 32B are higher than the melting point of the solder balls 35 due to the diffusion of the metal powder component in the solder bumps 12B, the solder balls 21, the solder balls 24 and the solder bumps 32B, as stated above.

Thus, similar to the semiconductor module of FIG. 1G, the semiconductor module of FIG. 9F is also free from the disadvantages as explained with reference to FIGS. 4A and 4B, FIGS. 5A and 5B, FIGS. 6A and 6B, FIGS. 7A and 7B and FIGS. 8A and 8B.

In the above-mentioned second embodiment of FIGS. 9A to 9F, as explained with reference to FIG. 2A, a piece of metal paste may be applied to a free end face of each of the solder bumps 32B of the flip-chip type semiconductor device 32 as a substitute for the piece of metal paste 31 (see: FIG. 9A) deposited on each of the electrode pads 30A on the top surface of the wiring board 30.

Similarly, in the above-mentioned second embodiment, as explained with reference to FIG. 2B, a piece of metal paste may be applied to each of the solder balls 24 of the wiring board 20 as a substitute for the piece of metal paste 34 (see: FIG. 9D) deposited on each of the electrode pads 30B on the top surface of the wiring board 30.

Also, in the above-mentioned second embodiment, as explained with reference to FIG. 3, the flip-chip type semiconductor device 32 may be provided on the bottom surface of the wiring board 30.

### Third Embodiment

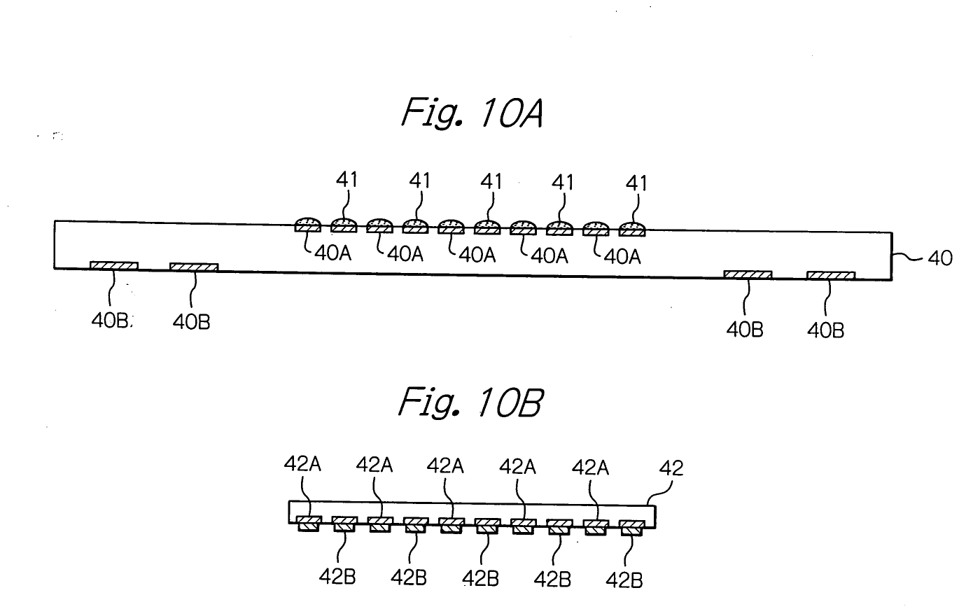

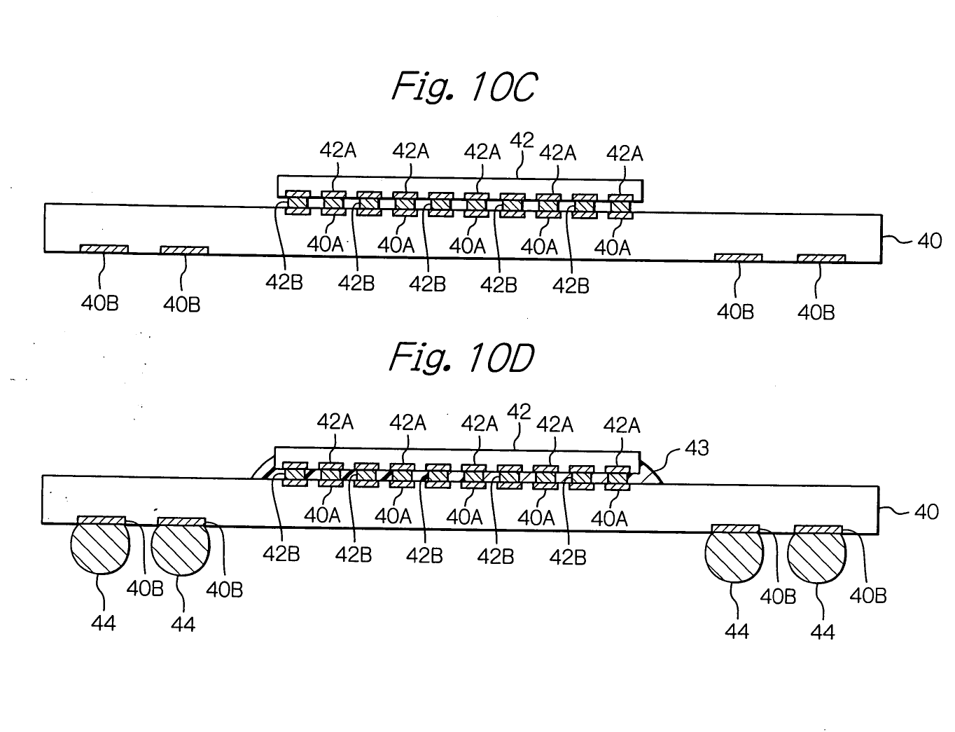

With reference to FIGS. 10A to 10D which are cross-sectional views, a third embodiment of the method for manufacturing the semiconductor module according to the present invention will now be explained below.

First, referring to FIG. 10A, a wiring board 40, which is called an interposer or a package board, is prepared. The wiring board 40 has a plurality of electrode pads 40A formed on a top surface thereof, and a plurality of electrode pads 40B formed on a bottom surface thereof. A piece of metal paste 41, which is composed of a flux solution component and a metal powder component, is deposited on each of the electrode pads 40A by using a silk printing process.

Note that the metal powder component may be gold (Au), bismuth (Bi) or the like. Also, note that the metal powder component features a size or diameter of at most 5 μm, and the size or diameter preferably falls within the range between 2 μm and 5 μm.

On the other hand, referring to FIG. 10B, a flip-chip type semiconductor chip 42 is prepared. The flip-chip type semiconductor chip 42 has a plurality of electrode pads 42A formed on a front face thereof, and a plurality of solder bumps 42B soldered to the electrode pads 42A, with each of the solder bumps 42B serving as an electrode terminal. Note that the solder bumps 42B have a predetermined melting point.

Next, referring to FIG. 10C, the flip-chip type semiconductor chip 42 is mounted on the wiring board 40 such that the solder bumps 42B are rested on the respective electrode pads 40A with the pieces of metal paste 41 (see: FIG. 10A), and then are subjected to a reflow process in which the solder bumps 42B are soldered to the respective electrode pads 40A on the top surface of the wiring board 40.

In particular, in the ref low process, both the wiring board 40 and the flip-chip type semiconductor device 42 are exposed to a hot air stream which is heated to the melting point of the solder bumps 42B so that the solder bumps 42B are thermally fused, and then are exposed to a cool air stream so that the fused solder bumps 42B are set, resulting in completion of the soldering of the solder bumps 42B to the respective electrode pads 40A on the top surface of the wiring board 40.

When each of the solder bumps 42B is thermally fused in the ref low process, the metal powder component contained in each of the pieces of metal paste 41 (see: FIG. 10A) is diffused as an additional metal component in the fused solder bump 42B concerned, so that the set solder bumps 42B exhibit a higher melting point than the original melting point thereof. In short, the melting point of the solder bumps 42B becomes higher due to the diffusion of the metal powder component in the solder bumps 42B.

Next, referring to FIG. 10D, after the soldering of the solder bumps 42B to the electrode pads 40A on the top surface of the wiring board 40 is completed, the f lip-chip type semiconductor device 42 is subjected to an underfilling process in which a suitable resin material is introduced into a space between the wiring board 40 and the flip-chip type semiconductor device 42 to thereby form a sealing resin layer 43 therebetween. Namely, the electrode pads 40A, the electrode pads 42A and the solder bumps 42B are sealed and protected by the sealing resin layer 43.

After the formation of the sealing resin layer 43 is completed, a plurality of solder balls 44 are soldered as external electrode terminals to the electrode pads 40B on the bottom surface of the wiring board 40, resulting in completion of a production of a semiconductor module as a flip-chip type package including the wiring board or interposer 40, the flip-chip type semiconductor chip 42 and the sealing resin layer 43.

Note that the solder balls 44 are formed of the same solder material as that used for the solder bumps 42B, so that the solder balls 44 have the same melting point as the original melting points of the solder bumps 42B in which the metal powder component such as gold (A), bismuth (Bi) or the like is not diffused.

When the semiconductor module of FIG. 10D is mounted on a motherboard (not shown), it is subjected to a reflow process in which the respective solder balls 44 are soldered on electrode pads formed on the motherboard.

Namely, in the reflow process, the semiconductor module of FIG. 10D is exposed to a hot air stream which is heated to the melting point of the solder balls 44, so that the solder balls 44 are thermally fused, and then are exposed to a cool air stream so that the fused solder balls 44 are set, resulting in completion of the soldering of the solder balls 44 to the respective electrode pads on the motherboard (not shown).

At this time, it is possible to carry out the soldering of the solder balls 44 to the respective electrode pads on the motherboard (not shown) without thermally fusing the solder bumps 42B, because the melting points of the solder bumps 42B are higher than the melting point of the solder balls 44 due to the diffusion of the metal powder component in the solder bumps 42B, as stated above.

Thus, the semiconductor module of FIG. 10D is free from the disadvantages as explained with reference to FIGS. 6A and 6B, FIGS. 7A and 7B and FIGS. 8A and 8B.

In the above-mentioned third embodiment of FIGS. 10A to 10D, as explained with reference to FIG. 2A, a piece of metal paste may be applied to a free end face of each of the solder bumps 42B of the flip-chip type semiconductor device 42 as a substitute for the piece of metal paste 41 (see: FIG. 10A) deposited on each of the electrode pads 40A on the top surface of the wiring board 40.

### Fourth Embodiment

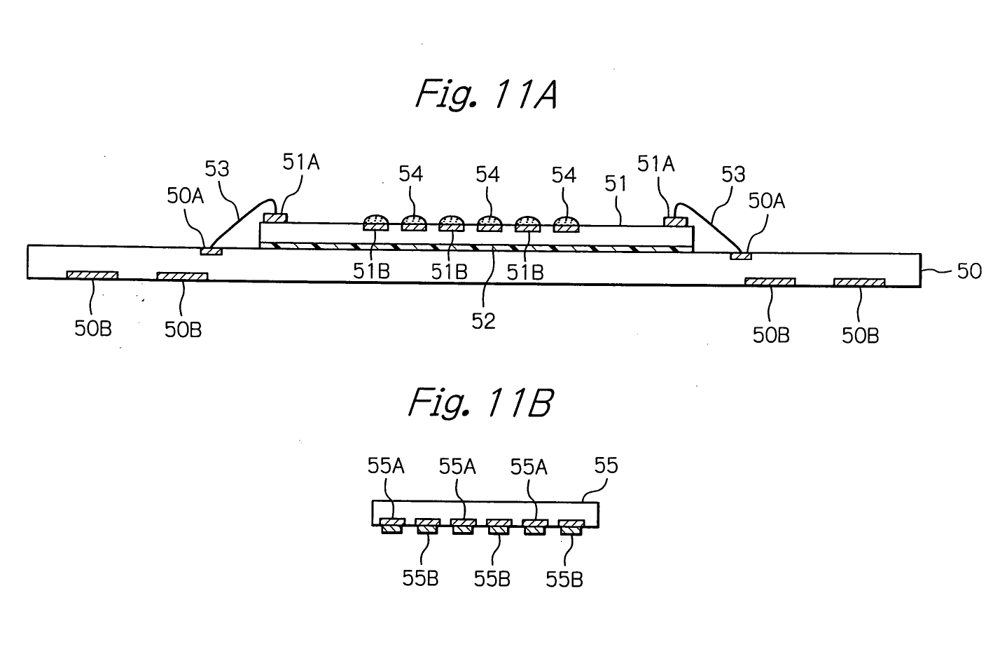

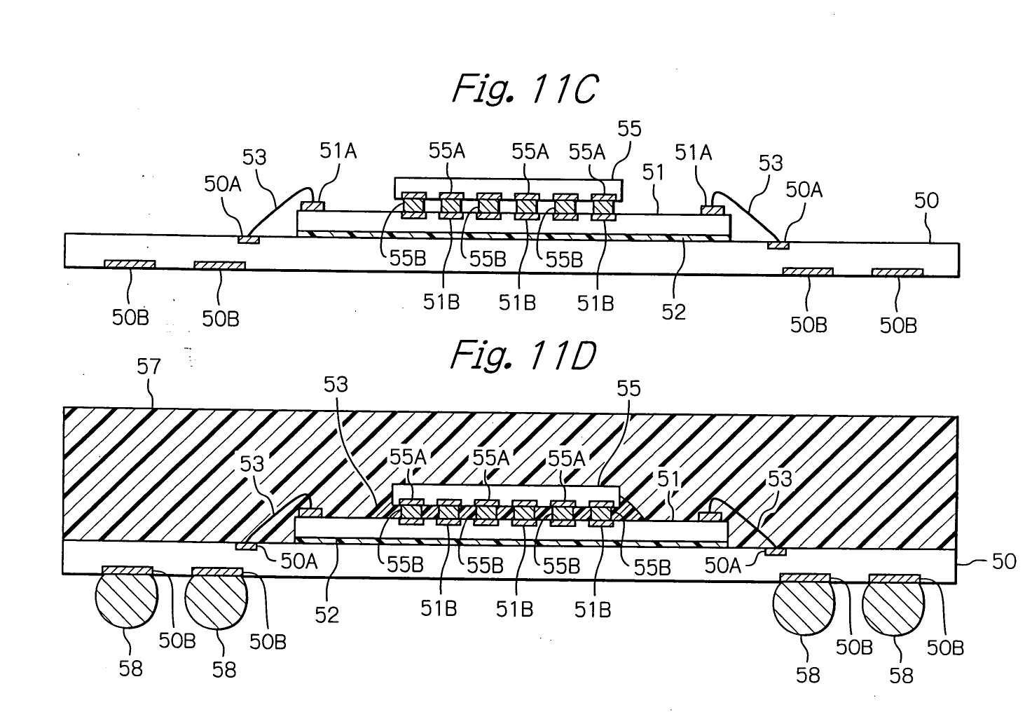

With reference to FIGS. 11A to 11D which are cross-sectional views, a fourth embodiment of the method for manufacturing the semiconductor module according to the present invention will now be explained below.

First, referring to FIG. 11A, a wiring board 50, which is called an interposer or a package board, is prepared. The wiring board 50 has a plurality of electrode pads 50A formed on a top surface thereof, and a plurality of electrode pads 50B formed on a bottom surface thereof.

A semiconductor device (chip) 51 is mounted on the wiring board 50 so that a rear face of the semiconductor device 51 is adhered to a top surface of the wiring board 50 by using a suitable adhesive layer 52. The semiconductor device 51 has a plurality of electrode pads 51A and 51B formed on a front face thereof. Each of the electrode pads 51A is electrically connected to any one of the electrode pads 50A on the wiring board 50 by a bonding wire 53, using a wire bonding machine (not shown).

After the mounting of the semiconductor device 51 on the wiring board 50 is completed, a piece of metal paste 54, which is composed of a flux solution component and a metal powder component, is deposited on each of the electrode pads 50A by using a silk printing process.

Note that the metal powder component may be gold (Au), bismuth (Bi) or the like. Also, note that the metal powder component features a size or diameter of at most 5 μm, and that the size or diameter preferably falls within a range between 2 μm and 5 μm.

On the other hand, referring to FIG. 11B, a flip-chip type semiconductor chip 55 is prepared. The flip-chip type semiconductor chip 55 has a plurality of electrode pads 55A formed on a front face thereof, and a plurality of solder bumps 55B soldered to the electrode pads 55A, with each of the solder bumps 55B serving as an electrode terminal. Note that the solder bumps 55B have a predetermined melting point.

Next, referring to FIG. 11C, the flip-chip type semiconductor chip 55 is mounted on the wiring board 50 such that the solder bumps 55B are rested on the respective electrode pads 51B with the pieces of metal paste 54 (see: FIG. 11A), and then are subjected to a reflow process in which the solder bumps 55B are soldered to the respective electrode pads 51B on the front face of the semiconductor device 51.

In particular, in the reflow process, both the wiring board 50, the semiconductor device 51 and the flip-chip type semiconductor device 55 are exposed to a hot air stream which is heated to the melting point of the solder bumps 55B so that the solder bumps 55B are thermally fused, and then are exposed to a cool air stream so that the fused solder bumps 55B are set, resulting in completion of the soldering of the solder bumps 55B to the respective electrode pads 51B on the front face of the semiconductor device 51.

When each of the solder bumps 55B is thermally fused in the reflow process, the metal powder component contained in each of the pieces of metal paste 54 (see: FIG. 11A) is diffused as an additional metal component in the fused solder bump 55B concerned, so that the set solder bumps 55B exhibits a higher melting point than the original melting point thereof. In short, the melting point of the solder bumps 55B becomes higher due to the diffusion of the metal powder component in the solder bumps 55B.

Next, referring to FIG. 11D, after the soldering of the solder bumps 55B to the electrode pads 51B on the front face of the semiconductor device 51 is completed, the flip-chip type semiconductor device 55 is subjected to an underfilling process in which a suitable resin material is introduced into a space between the semiconductor device 51 and the flip-chip type semiconductor device 55 to thereby form a sealing resin layer 56 therebetween. Namely, the electrode pads 51B, the electrode pads 55A and the solder bumps 55B are sealed and protected by the sealing resin layer 56.

After the formation of the sealing resin layer 56 is completed, a sealing resin layer 57 is formed over the top surface of the wiring board 50 so that the semiconductor device 51, the flip-chip type semiconductor device 55, the bonding wiring 53 and so on are sealed and protected by the sealing rein layer 57. Then, a plurality of solder balls 58 are soldered as external electrode terminals to the electrode pads 50B on the bottom surface of the wiring board 50, resulting in completion of a production of a semiconductor module as a chip-on-chip type package including the wiring board or interposer 50, the semiconductor device 51, the flip-chip type semiconductor chip 55 and the sealing resin layer 57.

Note that the solder balls 58 are formed of the same solder material as that used for the solder bumps 55B, so that the solder balls 58 have the same melting point as the original melting points of the solder bumps 55B in which the metal powder component such as gold (A), bismuth (Bi) or the like is not diffused.

When the semiconductor module of FIG. 11D is mounted on a motherboard (not shown), it is subjected to a reflow process in which the respective solder balls 58 are soldered on electrode pads formed on the motherboard.

Namely, in the reflow process, the semiconductor module of FIG. 11D is exposed to a hot air stream which is heated to the melting point of the solder balls 58, so that the solder balls 58 are thermally fused, and then are exposed to a cool air stream so that the fused solder balls 58 are set, resulting in completion of the soldering of the solder balls 58 to the respective electrode pads on the motherboard (not shown).

At this time, it is possible to carry out the soldering of the solder balls 58 to the respective electrode pads on the motherboard (not shown) without thermally fusing the solder bumps 55B, because the melting points of the solder bumps 55B are higher than the melting point of the solder balls 58 due to the diffusion of the metal powder component in the solder bumps 55B, as stated above.

Thus, the semiconductor module of FIG. 11D is free from the disadvantages as explained with reference to FIGS. 6A and 6B, FIGS. 7A and 7B and FIGS. 8A and 8B.

In the above-mentioned fourth embodiment of FIGS. 11A to 11D, as explained with reference to FIG. 2A, a piece of metal paste may be applied to a free end face of each of the solder bumps 55B of the flip-chip type semiconductor device 55 as a substitute for the piece of metal paste 54 (see: FIG. 11A) deposited on each of the electrode pads 51B on the front face of the semiconductor device 51.

### Fifth Embodiment

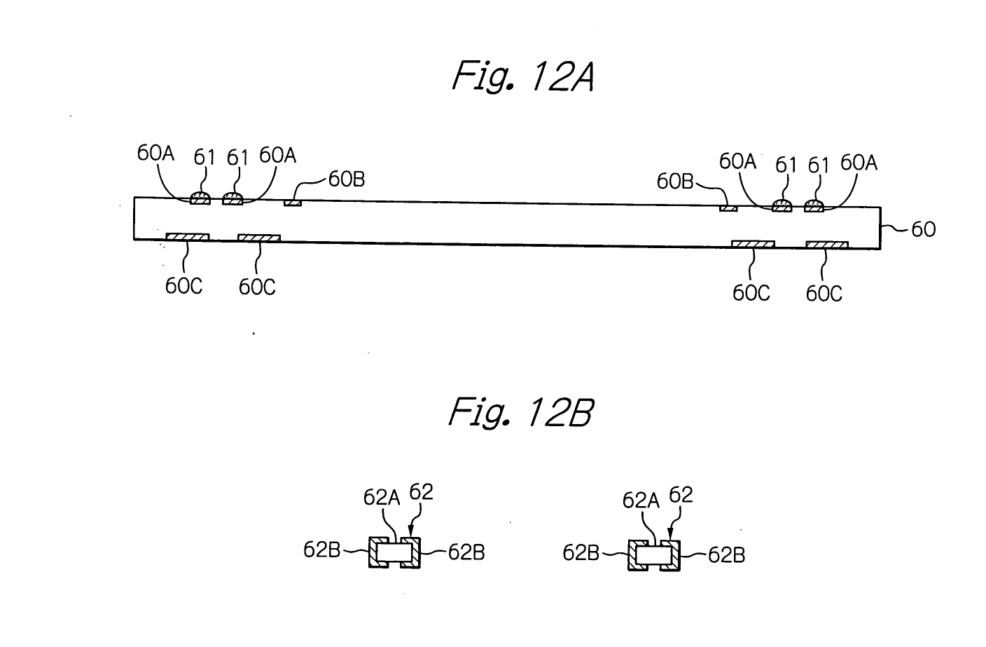

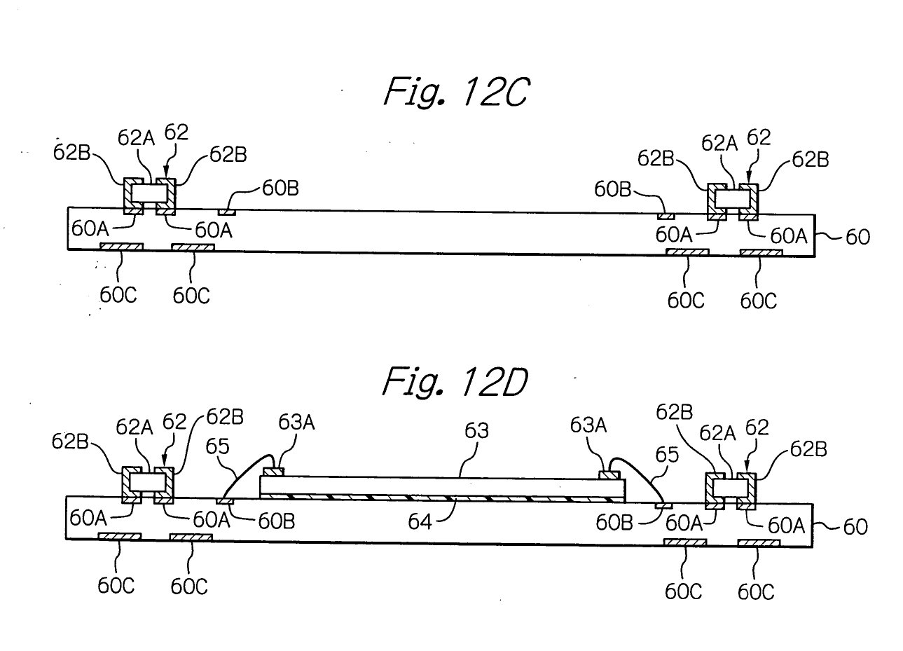

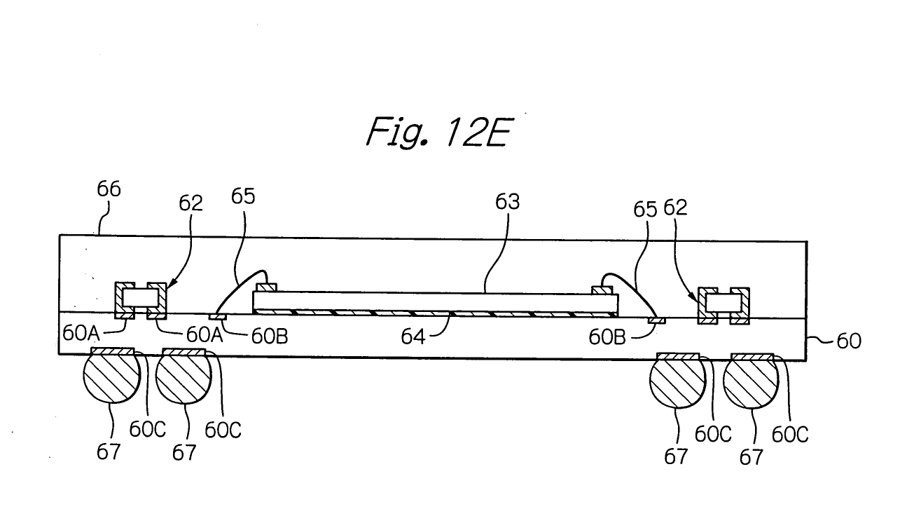

With reference to FIGS. 12A to 12E which are cross-sectional views, a fifth embodiment of the method for manufacturing the semiconductor module according to the present invention will now be explained below.

First, referring to FIG. 12A, a wiring board 60, which is called an interposer or a package board, is prepared. The wiring board 60 has plural pairs of electrode pads 60A formed on a top surface thereof, and a plurality of electrode pads 60B formed on the top surface thereof, and a plurality of electrode pads 60C formed on a bottom surface thereof.

A piece of metal paste 61, which is composed of a flux solution component and a metal powder component, is deposited on each of the electrode pads 60A by using a silk printing process.

Note that the metal powder component may be gold (Au), bismuth (Bi) or the like. Also, note that the metal powder component features a size or diameter of at most 10 μm, and that the size or diameter preferably falls within a range between 5 μm and 10 μm.

On the other hand, referring to FIG. 12B, a plurality of passive element devices 62 are prepared. Each of the passive element devices 62 includes a passive element 62A such as a resistor, a capacitor or an inductor, and a pair of solder electrode terminals 62B for holding the passive element 62A. Each of the solder electrode terminals 62B is made of a conductive core coated with a suitable solder material having a predetermined melting point.

Next, referring to FIG. 12C, each of the passive element device 62 is mounted on the wiring board 60 such that the solder electrode terminals 62B of the passive element device 62 are rested on a corresponding pair of electrode pads 60A with the pieces of metal paste 61 (see: FIG. 12A), and then are subjected to a reflow process in which the solder electrode terminals 62B are soldered to the corresponding electrode pads 60A on the top surface of the wiring board 60.

In particular, in the reflow process, the wiring board 60 with the passive element device 62 is exposed to a hot air stream which is heated to the melting point of the solder electrode terminals 62B so that the solder electrode terminals 62B are thermally fused, and then are exposed to a cool air stream so that the fused solder electrode terminals 62B are set, resulting in completion of the soldering of the solder electrode terminals 62B to the electrode pads 60A on the top surface of the wiring board 60.

When each of the solder electrode terminals 62B is thermally fused in the reflow process, the metal powder component contained in each of the pieces of metal paste 61 (see: FIG. 12A) is diffused as an additional metal component in the fused solder electrode terminal 62B concerned, so that the set solder electrode terminal 62B exhibits a higher melting point than the original melting point thereof. In short, the melting point of the solder electrode terminal 62B becomes higher due to the diffusion of the metal powder component in the solder electrode terminal 62B.

Next, referring to FIG. 12D, after the soldering of the solder electrode terminal 62B to the electrode pads 60A on the top surface of the wiring board 60 is completed, a semiconductor device (chip) 63 is mounted on the wiring board 60 such that a rear face of the semiconductor device 63 is adhered to the top surface of the wiring board 60 by using a suitable adhesive layer 64.

The semiconductor device 63 has a plurality of electrode pads 63A formed on a front face thereof, and each of the electrode pads 63A is electrically connected to any one of the electrode pads 60B on the top surface of the wiring board 60 by a bonding wire 65.

Next, referring to FIG. 12E, a sealing resin layer 66 is formed over the top surface of the wiring board 60 so that the passive element devices 62, the semiconductor device 63, the bonding wires 65 and so on are sealed and protected by the sealing rein layer 66. Then, a plurality of solder balls 67 are soldered as external electrode terminals to the electrode pads 60C on the bottom surface of the wiring board 60, resulting in completion of a production of a semiconductor module including the wiring board or interposer 50, the passive element devices 62, the semiconductor device 63 and the sealing resin layer 66.

Note that the solder balls 67 are formed of the same solder material as that used for the solder electrode terminals 62B, so that the solder balls 67 have the same melting point as the original melting points of the solder electrode terminals 62B in which the metal powder component such as gold (A), bismuth (Bi) or the like is not diffused.

When the semiconductor module of FIG. 12E is mounted on a motherboard (not shown), it is subjected to a reflow process in which the respective solder balls 67 are soldered on electrode pads formed on the motherboard.

Namely, in the reflow process, the semiconductor module of FIG. 12E is exposed to a hot air stream which is heated to the melting point of the solder balls 67, so that the solder balls 67 are thermally fused, and then are exposed to a cool air stream so that the fused solder balls 67 are set, resulting in completion of the soldering of the solder balls 67 to the respective electrode pads on the motherboard (not shown).

At this time, it is possible to carry out the soldering of the solder balls 68 to the respective electrode pads on the motherboard (not shown) without thermally fusing the solder electrode terminals 62B of the passive element devices 62, because the melting points of the solder electrode terminals 62B are higher than the melting point of the solder balls 67 due to the diffusion of the metal powder component in the solder electrode terminals 62B, as stated above.

In the above-mentioned fifth embodiment, if the solder electrode terminals 62B of the passive element devices 62 have the melting point which is equivalent to that of the solder balls 67, the semiconductor module of FIG. 12E may suffer disadvantages due to the fact that a fine clearance and a fine void are apt to be defined in the seal resin layer 66 around the passive element devices 62, as will be stated below.

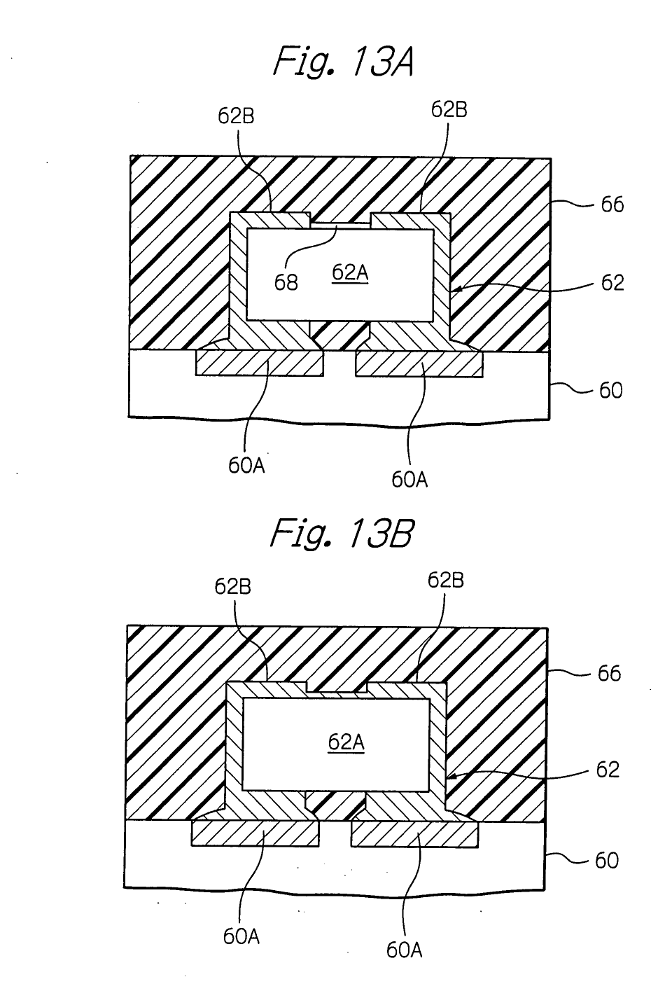

First, referring to FIG. 13A which is an enlarged cross-sectional view, the passive element device 62 is sealed in the seal resin layer 66, but a fine clearance 68 may be defined in the seal resin layer 66 at a top surface of the passive element 62A between the solder electrode terminals 62B.

Next, referring to FIG. 13B which is similar to FIG. 13A, during the reflow process of the solder balls 67 (see: FIG. 12E), the solder electrode terminals 62B are thermally fused so that the fused solder material may penetrate into the clearance 68 due to a capillary phenomenon, resulting in occurrence of a short circuit between the solder electrode terminals 62B.

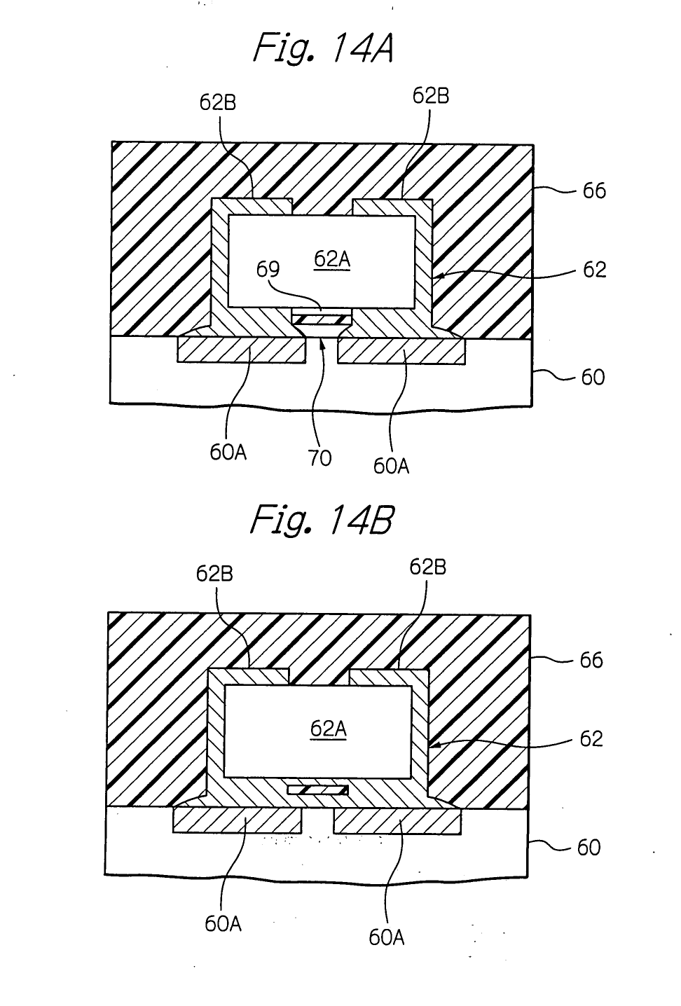

Also, referring to FIG. 14A which is an enlarged cross-sectional view, the passive element device 62 is sealed in the seal resin layer 66, but fine clearances 69 and 70 may be defined in the seal resin layer 66 at a bottom surface of the passive element 62A between the solder electrode terminals 62B.

Next, referring to FIG. 14B which is similar to FIG. 14A, during the reflow process of the solder balls 62 (see: FIG. 12E), the solder electrode terminals 62B are thermally fused so that the fused solder material may penetrate into the clearances 69 and 70 due to a capillary phenomenon, resulting in occurrence of a short circuit between the solder electrode terminals 62B.

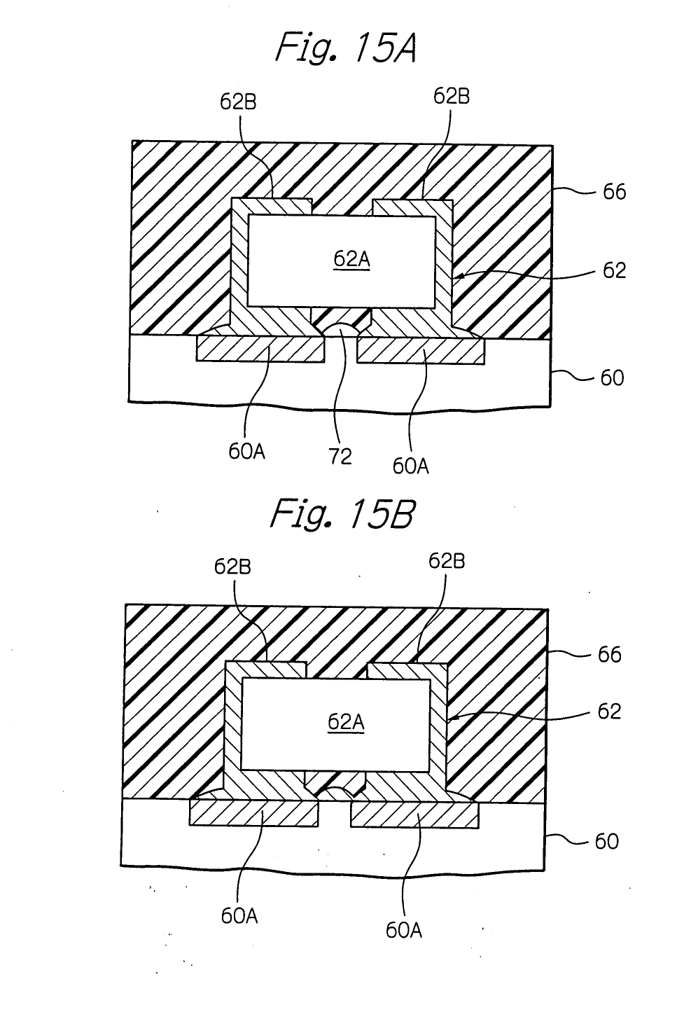

Further, referring to FIG. 15A which is an enlarged cross-sectional view, the passive element device 62 is sealed in the seal resin layer 66, but a fine void 72 may be defined in the seal resin layer 66 beneath the bottom surface of the passive element 62A between the solder electrode terminals 62B.

Next, referring to FIG. 15B which is similar to FIG. 15A, during the reflow process of the solder balls 66 (see: FIG. 12E), the solder electrode terminals 62B are thermally fused so that the fused solder material may penetrate into the to void 72 due to a capillary phenomenon, resulting in occurrence of a short circuit between the solder electrode terminals 62B.

Nevertheless, in reality, in the semiconductor module of FIG. 12E, it is possible to carry out the soldering of the solder balls 67 on the electrode pads of the motherboard without thermally fusing (reflowing) the solder electrode terminals 62B of the passive element devices 62. Thus, although the fine clearances 68, 69 and 70 and the void 72 are defined in the seal resin layer 66 around the passive element devices 62, the semiconductor module of FIG. 12E is free from the aforesaid short circuit problem (see: FIGS. 13A and 13B, FIGS. 14A and 14B and FIGS. 15A and 15B).

In the above-mentioned fifth embodiment of FIGS. 12A to 12E, as explained with reference to FIG. 2A, apiece of metal paste may be applied to a lower end face of each of the solder electrode terminals 62B of the passive element device 62 as a substitute for the piece of metal paste 61 (see: FIG. 12A) deposited on each of the electrode pads 60A on the top surface of the wiring board 60.

Finally, it will be understood by those skilled in the art that the foregoing description is of preferred embodiments of the method and the module, and that various changes and modifications may be made to the present invention without departing from the spirit and scope thereof.

1. A semiconductor module comprising:
a wiring board having a bottom surface and a top surface;
a first solder electrode terminal having a given melting point and provided on the bottom surface of said wiring board;
an electrode pad provided on or above the top surface of said wiring board; and
a second solder electrode terminal soldered to said electrode pad at a temperature corresponding to the given melting point of said first solder electrode terminal by using a reflow process,
wherein said second solder electrode terminal contains an additional metal powder component diffused therein when being soldered to said electrode pad.

2. The semiconductor module as set forth in claim 1, wherein said additional metal powder component has a size or diameter of at most 10 μm.

3. The semiconductor module as set forth in claim 1, wherein said additional metal powder component comprises either gold (Au) or bismuth (Bi).

4. The semiconductor module as set forth in claim 1, wherein said first solder electrode terminal is composed of the same components as said second solder electrode terminal except for said additional metal powder component.

5. The semiconductor module as set forth in claim 1, further comprising an electronic device provided on the top surface of said wiring board, wherein said electrode pad is formed on the top surface of said wiring board, and wherein said second solder electrode terminal is defined as a solder electrode terminal for said semiconductor device.

6. The semiconductor module as set forth in claim 5, wherein said electronic device is defined as a flip-chip type semiconductor device, and wherein said second solder electrode terminal is defined as a solder bump for said flip-chip type semiconductor device.

7. The semiconductor module as set forth in claim 6, wherein said additional metal powder component has a size or diameter of at most 5 μm.

8. The semiconductor module as set forth in claim 5, wherein said electronic device is defined as a passive element device, and wherein said second solder electrode terminal is defined as a pair of solder electrode terminals for said passive element device.

9. The semiconductor module as set forth in claim 8, wherein said additional metal powder component has a size or diameter of at most 10 μm.

10. The semiconductor module as set forth in claim 1, further comprising a semiconductor device provided on the top surface of said wiring board, and a flip-chip type semiconductor device provided on said first semiconductor device, wherein said electrode pad is formed on said first semiconductor device, and wherein said second solder electrode terminal is defined as a solder bump for said flip-chip type semiconductor device.

11. The semiconductor module as set forth in claim 10, wherein said additional metal powder component has a size or diameter of at most 5 μm.

12. The semiconductor module as set forth in claim 1, further comprising a semiconductor package provided on the top surface of said wiring board, wherein said electrode pad is formed on the top surface of said wiring board, and wherein said second solder electrode terminal is defined as an external solder electrode terminal for said semiconductor package.

13. The semiconductor module as set forth in claim 12, wherein said additional metal powder component has a size or diameter of at most 10 μm.

14. A semiconductor module comprising:
a wiring board;
a first solder electrode terminal having a given melting point and provided on a bottom surface of said wiring board;
an electrode pad provided on the bottom surface of said wiring board; and
a second solder electrode terminal soldered to said electrode pad at a temperature corresponding to the given melting point of said first solder electrode terminal by using a reflow process,
wherein said second solder electrode terminal contains an additional metal powder component diffused therein when being soldered to said electrode pad.

15. The semiconductor module as set forth in claim 14, further comprising an electronic device provided on the bottom surface of said wiring board, wherein said second solder electrode terminal is defined as a solder electrode terminal for said electronic device.

16. A method for manufacturing a semiconductor module comprising:
preparing a wiring board having a bottom surface and a top surface;
providing a first solder electrode terminal having a given melting point on the bottom surface of said wiring board;
providing an electrode pad on or above the top surface of said wiring board;
soldering a second solder electrode terminal to said electrode pad at a temperature corresponding to the given melting point of said first solder electrode terminal by using a reflow process; and
diffusing an additional metal powder component in said second solder electrode terminal when said second solder electrode terminal is soldered to said electrode pad.

17. The method as set forth in claim 16, wherein the diffusing of said additional metal powder component in said second solder electrode terminal is carried out by previously depositing a metal paste on said electrode pad before said second solder electrode terminal is soldered to said electrode pad.

18. The method as set forth in claim 16, wherein the diffusing of said additional metal powder component in said second solder electrode terminal is carried out by previously applying a metal paste to said second solder electrode terminal before said second solder electrode terminal is soldered to said electrode pad.

19. The semiconductor module as set forth in claim 16, wherein said additional metal powder component has a size or diameter of at most 10 μm.

20. The semiconductor module as set forth in claim 16, wherein said additional metal powder component comprises either gold (Au) or bismuth (Bi).
